(19) United States
(12) Patent Application Publication
(10) Pub. No.: US 2026/0032858 A1
(43) Pub. Date: Jan. 29, 2026

(54) LIQUID COOLING BLOCK FOR PLUGGABLE OPTICAL MODULES

(71) Applicant: NOKIA SOLUTIONS AND NETWORKS OY, Espoo (FI)

(72) Inventor: Michael DICRISTOFORO, Bow, NH (US)

(21) Appl. No.: 18/784,325

(22) Filed: Jul. 25, 2024

(51) Int. Cl. H05K 7/20; G02B 6/42

(52) U.S. Cl. CPC H05K 7/20272; G02B 6/4251; G02B 6/4256; G02B 6/4269; G02B 6/4284

(57) ABSTRACT

A cooling arrangement includes a first liquid-coolant-block (LCB) defining a first enclosed volume, and has plurality of first-I/O ports, each first-I/O port providing access to the first enclosed volume, a second LCB, disposed adjacent the first LCB, defining a second enclosed volume, and having a plurality of second-I/O ports, each second-I/O port providing access to the second enclosed volume, and a first LCB-connector coupled between a first first-I/O port of the first LCB and a first second-I/O port of the second LCB, wherein the first LCB-connector includes a tube having an outer surface, a first end, and a second end, a first tube-ridge extending from the outer surface of the tube and disposed a first distance from the first end, a second tube-ridge extending from the outer surface of the tube and disposed a second distance from the first end.

### FIELD OF THE DISCLOSURE

Various exemplary embodiments disclosed herein relate to liquid cooling of optical modules.

### BACKGROUND

Advances in semiconductor manufacturing technology and digital communication designs have helped to enable great increases in the traffic-carrying capacity of packet-switched networks. At least partly in view of the capabilities and features of modern digital communication networks, these networks have been widely adopted, and now form an integral part of both wired and wireless communications and data transfers.

As the amount of data traffic has increased, the use of optical signalling technologies has been combined with the use of electronic data processing circuitry to provide high-bandwidth communication. For example, fiber optic cables may carry high-speed optical signals between various network devices, and those network devices may convert the received optical signals to electrical signals, carry out various logical or signal processing tasks, and convert the resulting electrical signals back to optical signals for transmission to another network device.

The widespread use of optical signalling between network devices has led to the development and deployment of optical transceiver modules for use in digital communication networks.

### SUMMARY

A summary of various illustrative embodiments is presented below.

According to an aspect of this disclosure a liquid-coolant-block-subassembly configured to engage with a liquid-coolant-block for liquid communication includes a housing defining a main-enclosed-volume, the housing having a housing-wall, a first inlet/outlet (I/O) port defining a first liquid-communication-path through the housing-wall at a first location thereof, the first liquid-communication-path coupled to the main-enclosed-volume, a second I/O port defining a second liquid-communication-path through the housing-wall at a second location thereof, the second liquid-communication-path coupled to the main-enclosed-volume, and a first liquid-coolant-block-connector having a first end, a second end, and a first outer surface, wherein the first end is engaged with the first I/O port such that the first liquid-coolant-block-connector maintains a liquid-tight seal between the first I/O port and the first outer surface of the first liquid-coolant-block-connector through a range of angular displacement of the housing relative to the second end of the liquid-coolant-block-connector.

In some embodiments, the first I/O port includes a first outer-opening having a first outer-opening-diameter at the first location of the housing-wall and a first inner-opening disposed inwardly from the first outer-opening, the first inner-opening having a first inner-opening-diameter that is less than the first outer-opening-diameter, and the housing-wall is chamfered between the first outer-opening and the first inner-opening.

In some embodiments, the liquid-coolant-block-subassembly further includes a second liquid-coolant-block-connector having a third end, a fourth end, and a second outer surface, wherein the third end is engaged with the second I/O port such that the second liquid-coolant-block-connector maintains a liquid-tight seal between the second I/O port and the second outer surface of the second liquid-coolant-block-connector through a range of angular displacement of the housing relative to the fourth end of the second liquid-coolant-block-connector, and wherein the second I/O port includes a second outer-opening having a second outer-opening-diameter at the second location of the housing-wall and a second inner-opening disposed inwardly from the second outer-opening, the second inner-opening having a second inner-opening-diameter that is less than the second outer-opening-diameter, and the housing-wall is chamfered between the second outer-opening and the second inner-opening.

In some embodiments, the liquid-coolant-block-subassembly may further include a third I/O port defining a third liquid-communication-path through the housing-wall at a third location thereof, the third liquid-communication-path coupled to the main-enclosed-volume, and a fourth I/O port defining a fourth liquid-communication-path through the housing-wall at a fourth location thereof, the fourth liquid-communication-path coupled to the main-enclosed-volume, wherein the first liquid-coolant-block-connector comprises a tube having a first outer surface, a first end, and a second end opposite the first end, a first circumferential tube-ridge extending outwardly from the first outer surface and disposed a first distance from the first end, and a first O-ring disposed on the first outer surface of the tube and positioned adjacent to the first circumferential tube-ridge.

In some embodiments, the housing includes a metal, a plastic, and a heat slug.

According to another aspect of this disclosure, a cooling apparatus includes a first liquid-coolant-block (LCB), the first LCB defining a first enclosed volume, and having a plurality of first-inlet/outlet (I/O) ports, each first-I/O port of the plurality of first-I/O ports providing access to the first enclosed volume, a second LCB, disposed adjacent to the first LCB, defining a second enclosed volume, and having a plurality of second-I/O ports, each second-I/O port of the plurality of second-I/O ports providing access to the second enclosed volume, and a first LCB-connector coupled between a first first-I/O port of the first LCB and a first second-I/O port of the second LCB, wherein the first LCB-connector includes a tube having an outer surface, a first end, and a second end opposite the first end, a first circumferential tube-ridge extending outwardly from the outer surface of the tube and disposed a first distance from the first end, a second circumferential tube-ridge extending outwardly from the outer surface of the tube and disposed a second distance from the first end, a third circumferential tube-ridge extending outwardly from the outer surface of the tube and disposed the first distance from the second end, and a fourth circumferential tube-ridge extending outwardly from the outer surface of the tube and disposed the second distance from the second end.

In some embodiments, the first LCB-connector further includes a first O-ring disposed on the outer surface of the tube and positioned adjacent to the first circumferential tube-ridge, a second O-ring disposed on the outer surface of the tube and positioned between the first circumferential tube-ridge and the second circumferential tube-ridge, a third O-ring disposed on the outer surface of the tube and positioned adjacent to the third circumferential tube-ridge; and a fourth O-ring disposed on the outer surface of the tube and positioned between the third circumferential tube-ridge and the fourth circumferential tube-ridge.

In some embodiments, the cooling arrangement further includes a first plug disposed in a second first-I/O port, wherein the first plug includes a solid cylinder having an outer surface, a first end, and a second end opposite its first end, a first circumferential plug-ridge extending outwardly from the outer surface of the solid cylinder and disposed a third distance from its first end, a second circumferential plug-ridge extending outwardly from the outer surface of the solid cylinder and disposed a fourth distance from the first end, a fifth O-ring disposed on the outer surface of the solid cylinder and positioned adjacent to the first circumferential plug-ridge, and a sixth O-ring disposed on the outer surface of the solid cylinder and positioned between the first circumferential plug-ridge and the second circumferential plug-ridge.

In some embodiments, the first LCB includes a housing having a heat slug.

In some embodiments, the first LCB includes a housing having a plastic upper portion and a metal bottom portion.

According to a further aspect of this disclosure, a method of removing heat from a plurality of optical modules includes providing a substrate having a first optical-module-cage disposed thereon, and a second optical-module-cage disposed thereon, coupling a first liquid-coolant-block (LCB) and a second LCB to each other with a first LCB-connector, disposing the first LCB on the first optical-module-cage such that it is a first distance from the substrate, and disposing the second LCB on the second optical-module-cage such that it is the first distance from the substrate, applying a first spring force to maintain the first LCB in contact with the first optical-module-cage, applying a second spring force to maintain the second LCB in contact with the second optical-module-cage, inserting a first pluggable optical module in the first optical-module-cage, inserting a second pluggable optical module in the second optical-module-cage, supplying power to the first pluggable optical module and to the second optical module; and flowing a liquid coolant through the first LCB and the second LCB.

In some embodiments, the method of removing heat from a plurality of optical modules further includes coupling the first LCB and the second LCB to each other with a second LCB-connector.

In some embodiments of the method, the first LCB has a first inlet/outlet (I/O) port in a first sidewall, the first I/O port includes a first outer-opening having a first outer-opening-diameter, a first inner-opening disposed inwardly from the first outer-opening, the first inner-opening having a first inner-opening-diameter that is less than the first outer-opening-diameter, and the first sidewall is chamfered between the first outer-opening and the first inner-opening.

In some embodiments of the method, applying the first spring force includes disposing a resilient biasing element in contact with the first LCB.

In some embodiments, the method, of removing heat from a plurality of optical modules further includes connecting the first LCB to a coolant distribution unit.

### BRIEF DESCRIPTION OF DRAWINGS

To better understand various illustrative embodiments, reference is made to the accompanying drawings.

FIG. 1 is a perspective view of a housing for a system-level product that includes front panel configured to receive a plurality of plug-in optical modules.

FIG. 2 is a perspective view of the system-level product of FIG. 1 with the housing removed to show a conventional arrangement of optical-module-cages for receiving plug-in optical modules, and heat sinks with vertical fins disposed above the cages.

FIG. 3A is a front-facing perspective view of a substrate with optical-module-cages mounted thereon, and a liquid-cooling-block, in accordance with this disclosure, disposed on top of each optical-module-cage.

FIG. 3B is a rear-facing perspective view of a cooling arrangement in accordance with this disclosure, having a cross-sectional view of the back end of the liquid-cooling blocks showing an arrangement of liquid-cooling-block-connectors between liquid-cooling-blocks.

FIG. 4A is a perspective view of a liquid-coolant-block, in accordance with this disclosure.

FIG. 4B is an exploded perspective view of a liquid-coolant-block, in accordance with this disclosure, showing an upper portion of the liquid-coolant-block, a lower portion including a heat slug, and seals for preventing leakage of a coolant liquid from the assembled liquid-coolant-block.

FIG. 4C is a perspective view of an illustrative liquid-coolant-block in accordance with this disclosure.

FIG. 4D is a third angle projection of the liquid-coolant-block of FIG. 4C.

FIG. 4E is a cross-sectional view in the x-y plane of the liquid-coolant-block of FIG. 4C taken at the level of line A-A.

FIG. 4F is a cross-sectional view in the x-y plane of an alternative liquid-coolant-block in accordance with this disclosure.

FIG. 4G is a cross-sectional view in the x-z plane illustrating aspects of the sidewall I/O ports of a liquid-coolant-block in accordance with this disclosure.

FIG. 5A is a perspective view of a liquid-coolant-block-connector including O-rings disposed thereon in accordance with this disclosure.

FIG. 5B is a perspective view of a tube portion of an LCB-connector in accordance with this disclosure without O-rings disposed thereon.

FIG. 5C is a side view of the tube portion of the LCB-connector shown in FIG. 5B.

FIG. 5D is a cross-sectional view of FIG. 5C with O-rings added on the outer surface thereof in accordance with this disclosure.

FIG. 6 is a perspective view of a plug in accordance with this disclosure, with O-rings disposed thereon.

FIG. 7 illustrates a cooling arrangement in which the liquid-coolant-blocks, connectors, and plugs are configured such that liquid coolant may flow in parallel through the liquid-coolant-blocks.

FIG. 8 illustrates an alternative cooling arrangement in which the liquid-coolant-blocks, connectors, and plugs are configured such that coolant flows serially through the liquid-coolant-blocks.

FIG. 9A shows a vertical cross-section of the illustrative embodiment of FIG. 7.

FIG. 9B is an enlarged view of a portion of FIG. 9A.

FIG. 10 is a partially exploded perspective view illustrating liquid-coolant-blocks disposed on optical-module-cages and coupled for the flow of liquid coolant by liquid-coolant-block-connectors, in accordance with this disclosure.

FIG. 11A is a cross-sectional view of adjacent liquid-coolant-blocks coupled by a liquid-coolant-block connector, where one of the liquid-coolant-blocks is vertically offset with respect to the other liquid-coolant-block.

FIG. 11B is a cross-sectional view of adjacent liquid-coolant-blocks coupled by a liquid-coolant-block connector, where a restraining pin is provided for each liquid-coolant-block, passes through an upper side of the liquid-coolant-block and engages with a groove on the outer surface of the liquid-coolant-block connector.

FIG. 12 is a perspective view of an embodiment, in accordance with this disclosure, that includes resilient biasing elements and brackets to hold those elements in place.

FIG. 13 is a perspective view of an embodiment, in accordance with this disclosure, that provides a belly-to-belly arrangement that provides multiple rows of optical-module-cages.

FIG. 14 is a flow diagram of a method in accordance with this disclosure.

To facilitate understanding, identical reference numerals have been used to designate elements having substantially the same or similar structure and/or substantially the same or similar function.

### DETAILED DESCRIPTION

Various embodiments in accordance with this disclosure provide liquid-coolant-blocks (LCB) and LCB-connectors that may be configured for liquid cooling of plug-in, or pluggable, optical modules. The modular nature of embodiments in accordance with this disclosure allow for vertical movement of an individual coolant block while that individual coolant block is laterally connected to one or more non-moving coolant blocks. Such vertical movement occurs during the insertion or removal of pluggable optical modules. Such movement, or displacement, of LCBs may include a lateral component of movement and may thus be referred to more generally as angular displacement. The modular nature of embodiments in accordance with this disclosure further allows for several optical modules to be cooled concurrently regardless of whether the spacing between those several optical modules is nominally the same or different.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of, or combined with, any other aspect of the disclosure. For example, an apparatus may be implemented, or a method may be practiced, using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Many high-speed communication systems use a combination of optical data transmission and electronic signal processing. The widespread adoption of this combination is served, at least in part, by pluggable optical modules. Pluggable optical modules are alternatively referred to as plug-in optical modules. Such pluggable optical modules may provide a convenient way to couple fiber optic cables to various network devices quickly and efficiently. Typical pluggable optical modules configured to be easily inserted into, and removed from, a device such as a network device. The pluggable optical module may be inserted into, and removed from, an optical-module-cage which is internal to the network device and typically attached to a printed circuit board within the network device. The optical-module-cage typically provides an opening in a topside thereof to provide an area for making a thermal connection to the optical module. The pluggable optical module is further configured to be coupled with a fiber optic cable that is external to the network device.

These optical modules provide transceiver functionality, and may contain a number of components that generate heat when the modules are operating. For example, optical transceiver modules may contain, but are not limited to, a laser diode to generate an optical signal for transmission, a driver circuit to control the laser diode and thereby convert an electrical signal into an optical signal, a photodiode to convert incoming optical signals into corresponding electrical signals, and an amplifier (such as a transimpedance amplifier) to amplify the output of the photodiode. Some optical transceiver modules may include logic circuitry or a microcontroller to monitor various parameters such as optical output power, optical input power, laser bias current, temperature, and supply voltage. Some optical transceiver modules may include memory storage to store information about the module such as vendor information, serial number, part number, and operational parameters. All of these components may consumer power and consequently generate heat.

The heat generated by various components of a pluggable optical transceiver module may adversely affect its performance and/or its useful lifetime. There are various approaches to removing excess heat generated by pluggable optical transceiver modules. For example, a flow of cool air moving over the modules to carry away radiated heat; and metal heat sinks with vertical fins to assist with carrying the excess heat away from the modules and transferring it to air. However, as the data rates handled by optical transceiver modules increases, the amount of excess heat generated tends to increase, and consequently there is an increased need for cooling. With greater requirements for heat dissipation air cooling alone may be inadequate, and larger heat sinks may occupy an undesirably larger portion of a network device into which the optical transceiver module is plugged.

In accordance with this disclosure, a cooling arrangement is provided for the flow of a liquid coolant to remove excess heat from optical transceiver modules that are plugged into a device, such as but not limited to, a network device. Advantageously, liquid cooling in accordance with this disclosure can transport heat away from the optical transceiver modules more effectively that air cooling. Further advantageously, the physical structures for liquid cooling in accordance with this disclosure consume less space than corresponding metal heat sinks with vertical fins.

Various embodiments in accordance with this disclosure provide an individual spring-loaded LCB for each optical-module-cage of a plurality of optical-module-cages in a system such as, but not limited to, a network device, wherein adjacent LCBs are connected by tubes having O-rings that allow the LCBs to be interconnected for the flow of liquid coolant, while further allowing each LCB to individually move vertically during the insertion/removal of a pluggable optical transceiver module to/from an optical-module-cage.

In a liquid-cooling arrangement of various embodiments, individual LCBs are disposed over corresponding individual optical-module-cages. Each optical-module-cage has a topside opening such that the LCB disposed thereover makes physical contact with an optical module that has been inserted into the optical-module-cage. As used herein with respect to the optical-module-cages, the term “topside” refers to the side of the optical-module-cage that is furthest from the substrate on which the optical-module-cage is attached.

A desired thermal connection between an LCB and the optical module in the optical-module-cage over which the LCB is disposed, is maintained by a resilient biasing element. A resilient biasing element may be, but is not limited to, a spring such as a coil spring or a leaf spring. That is, in some embodiments, a spring force is used to maintain thermal contact between the LCB and the optical module.

A liquid coolant is circulated through the LCBs, and the LCBs are interconnected among themselves by LCB-connectors between adjacent LCBs. Heat generated by the operation of the optical modules may be transferred to, and removed by liquid coolant flowing through the LCBs.

It is noted that in various embodiments, different spacings between optical-module-cages typically corresponds to different spacings between interconnected LCBs. Such different spacings may be accommodated by using LCB-connectors having correspondingly different lengths.

In some embodiments, the LCB-connectors may be tubes with O-rings disposed thereon. In such embodiments, even though the LCBs are interconnected by the LCB-connectors, each LCB may individually move vertically to accommodate insertion or removal of an optical transceiver module without disturbing the fluid flow between adjacent LCBs. To reduce or eliminate disturbances to the fluid flow between adjacent LCBs, the LCB-connectors may cant when adjacent LCBs are vertically displaced, and O-rings on the outer surface of the LCB-connectors reduce or preclude leakage of the liquid coolant.

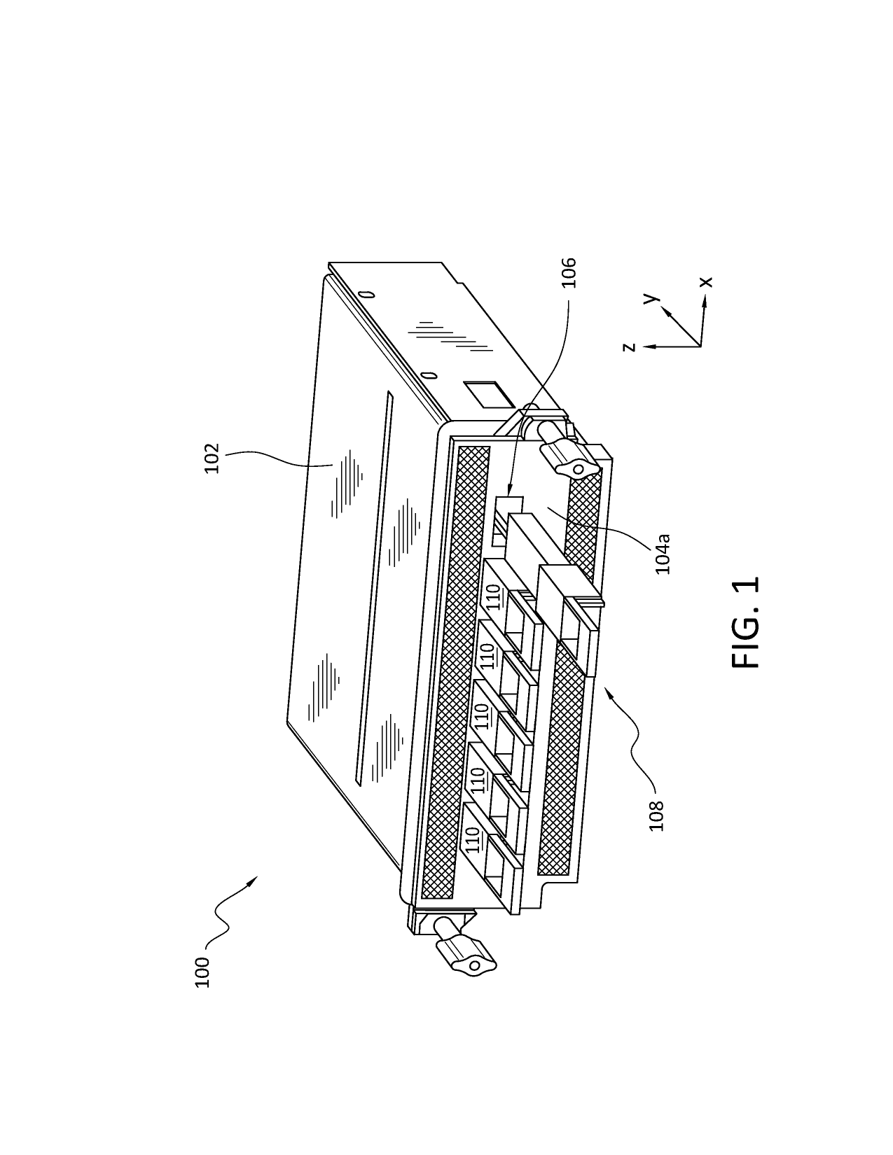

FIG. 1 shows a perspective view of a system-level product 100, such as a network device, that has a housing 102 including a front panel 104 a with openings 106 to receive an optical transceiver module 108. System-level product 100 is configured to receive a plurality of pluggable optical transceiver modules. Optical transceiver modules 110 are shown after they have been inserted, i.e., plugged into system-level product 100. System-level product 100 may be any product that uses heat-generating pluggable modules. System-level product 100 may be, but is not limited to a network device such as a data switch.

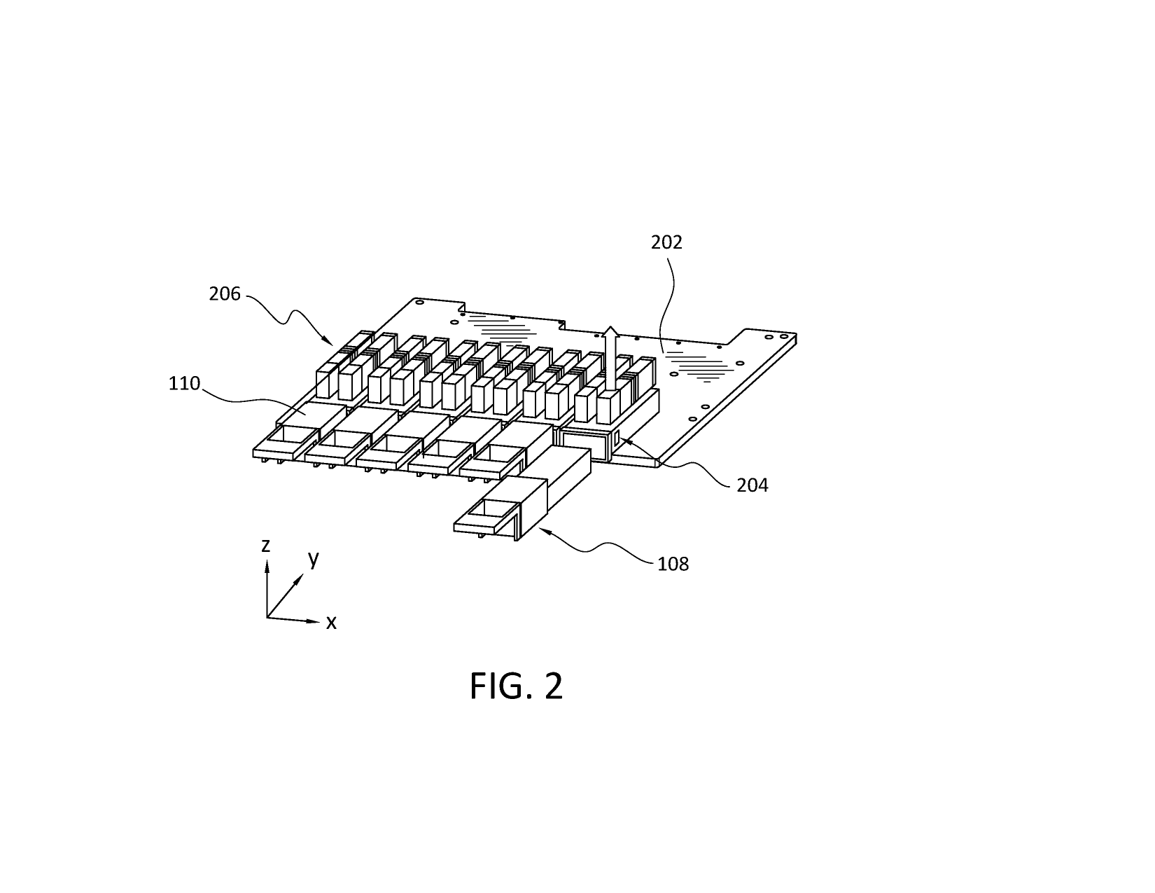

FIG. 2 is a perspective view of the system-level product of FIG. 1 with the housing removed to show a conventional arrangement where a printed circuit board 202 has a plurality of optical-module-cages 204 for receiving plug-in optical transceiver modules 108, 110, and heat sinks 206 with vertical fins disposed above the optical-module-cages 204. As mentioned above, the height of the vertical fins of heat sinks 206 may consume an undesirable amount of space within the housing of system-level product.

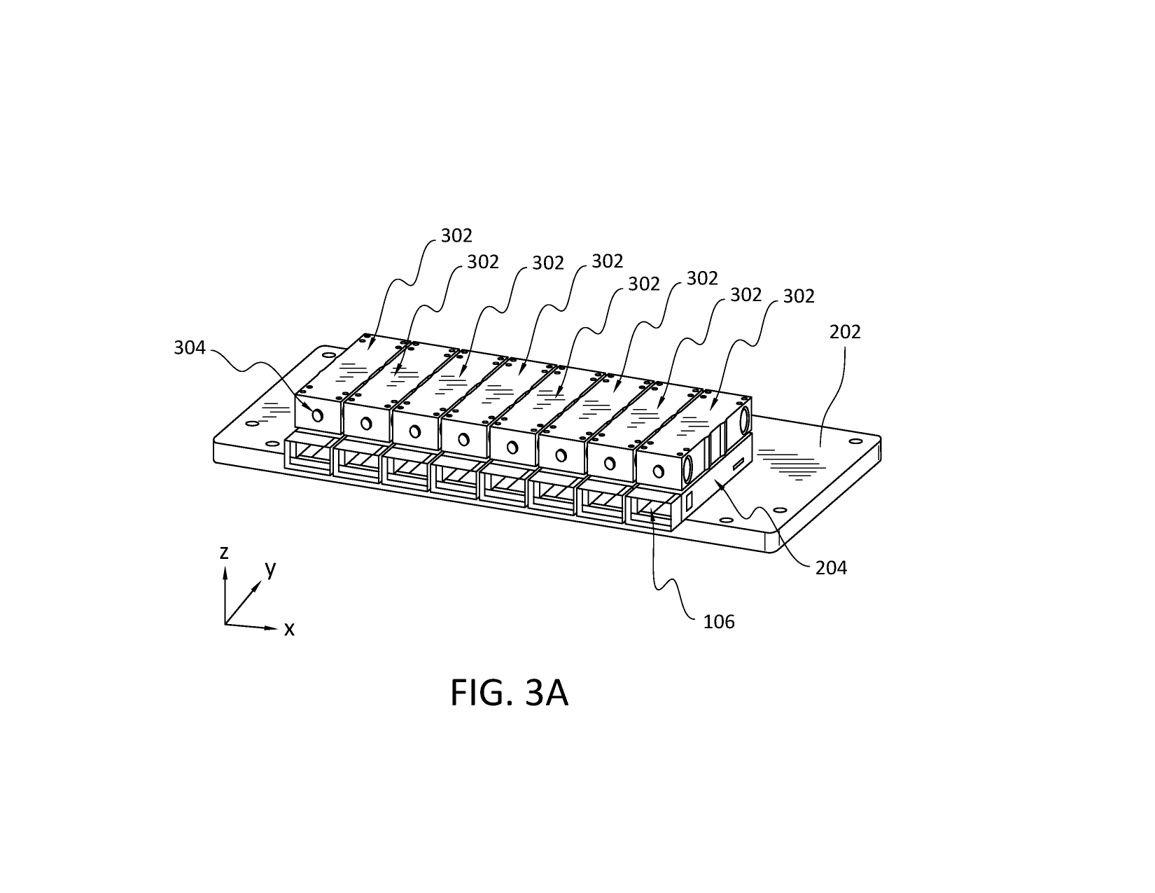

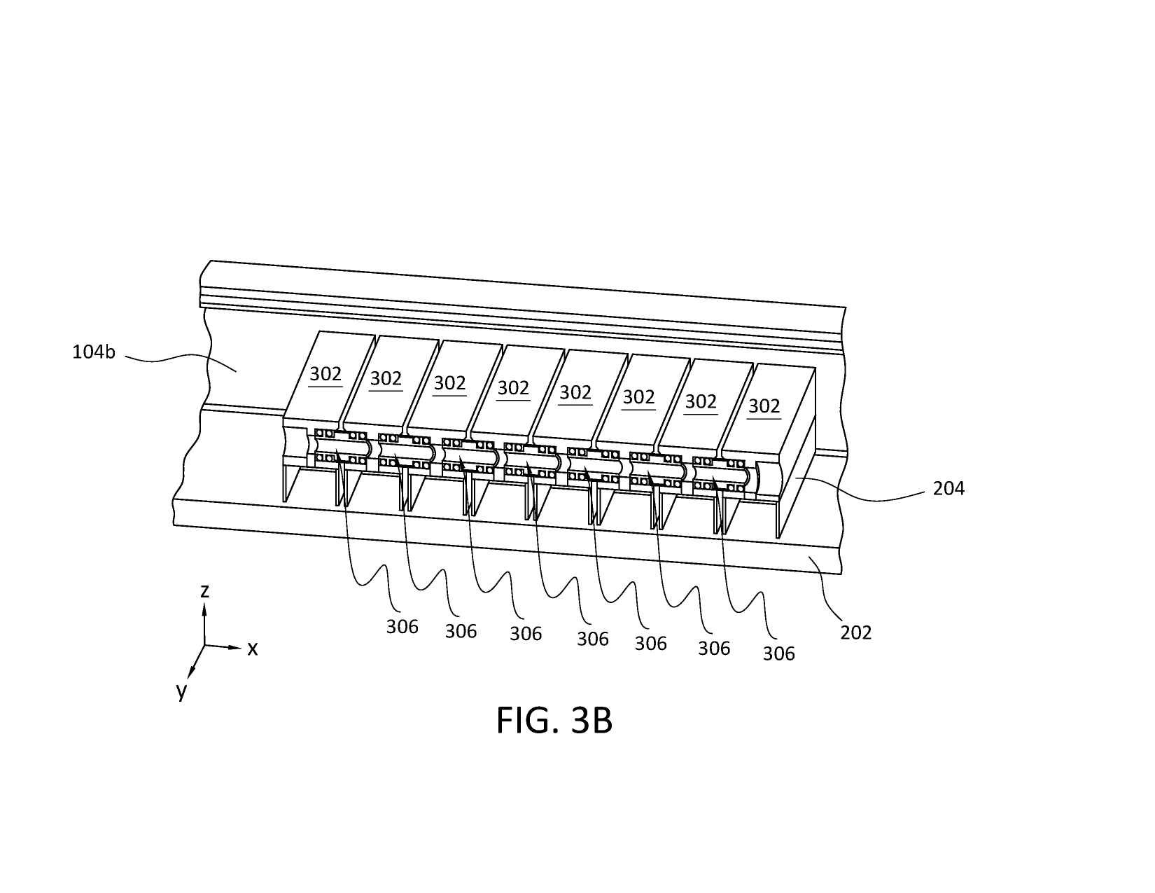

FIG. 3A illustrates a cooling arrangement in accordance with this disclosure. Here, an LCB having a lower profile than the vertical fins of a conventional metal heat sink is disposed on the topside of each optical-module-cage. FIG. 3A is a front-facing perspective view of a board-level product having a substrate 202 with optical-module-cages 204 attached thereto, and an LCB 302, in accordance with this disclosure, disposed on top of each optical-module-cage 204. In operation, a liquid coolant enters each LCB 302 by way of an inlet port, absorbs heat from an underlying optical transceiver module (not shown in FIG. 3A) and the exits the LCB through an outlet port. In some embodiments, the inlet ports and the outlet ports of the sidewalls of an LCB have the same physical configuration, and may be referred to as inlet/outlet (I/O) ports.

In various embodiments (as discussed in greater detail below), some LCBs have two I/O ports disposed on each of their sidewalls. The I/O ports on the sidewalls of such embodiments may be used as either inlet ports or output ports. The illustrative embodiment of FIG. 3A further has an I/O port on its frontside. In some embodiments, the frontside I/O port may be sealed with, for example, a set screw 304.

FIG. 3B provides another view of the cooling arrangement of FIG. 3A. FIG. 3B is a rear-facing perspective view of the board-level product providing a cooling arrangement in accordance with this disclosure. FIG. 3B shows a cross-sectional view of the back end of liquid-coolant blocks 302 showing an arrangement of liquid-coolant-block-connectors 306 between liquid-coolant-blocks. FIG. 3B also shows the backside, i.e., the internal side 104b of front panel 104a.

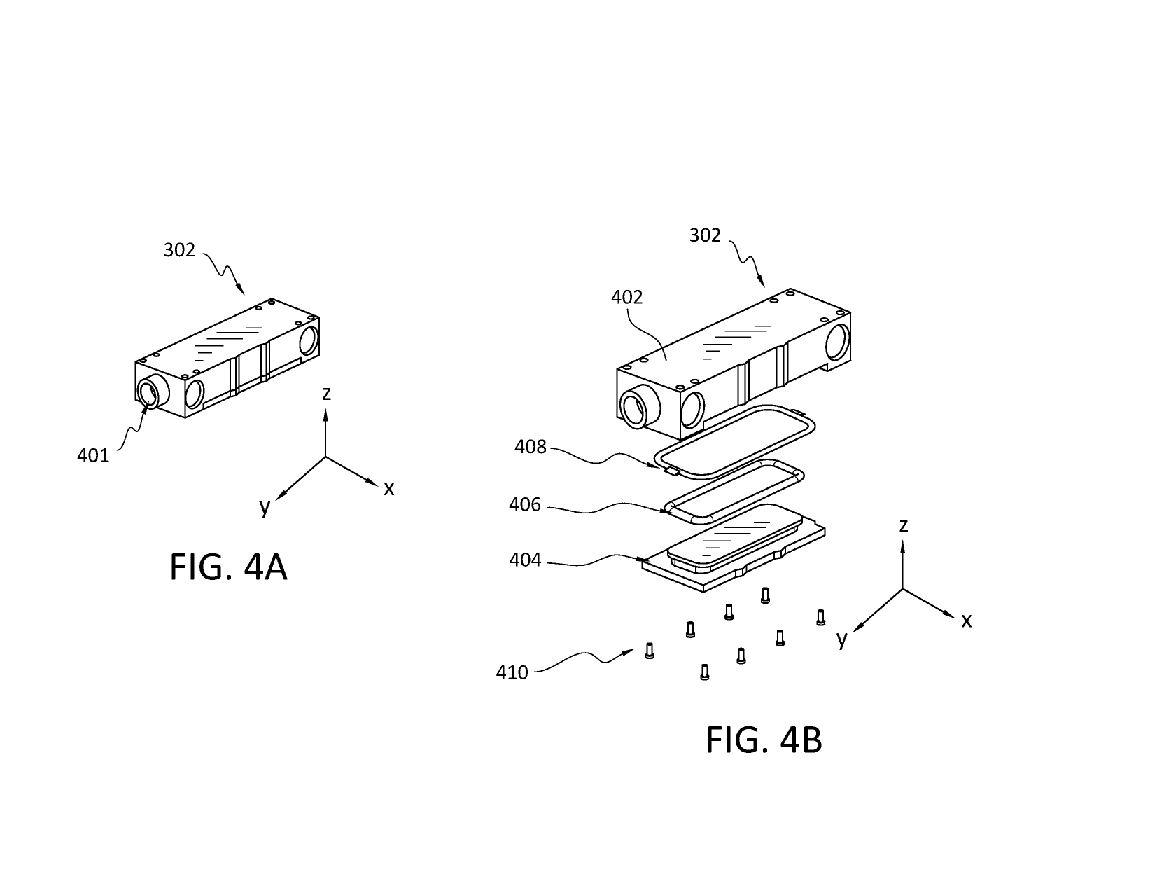

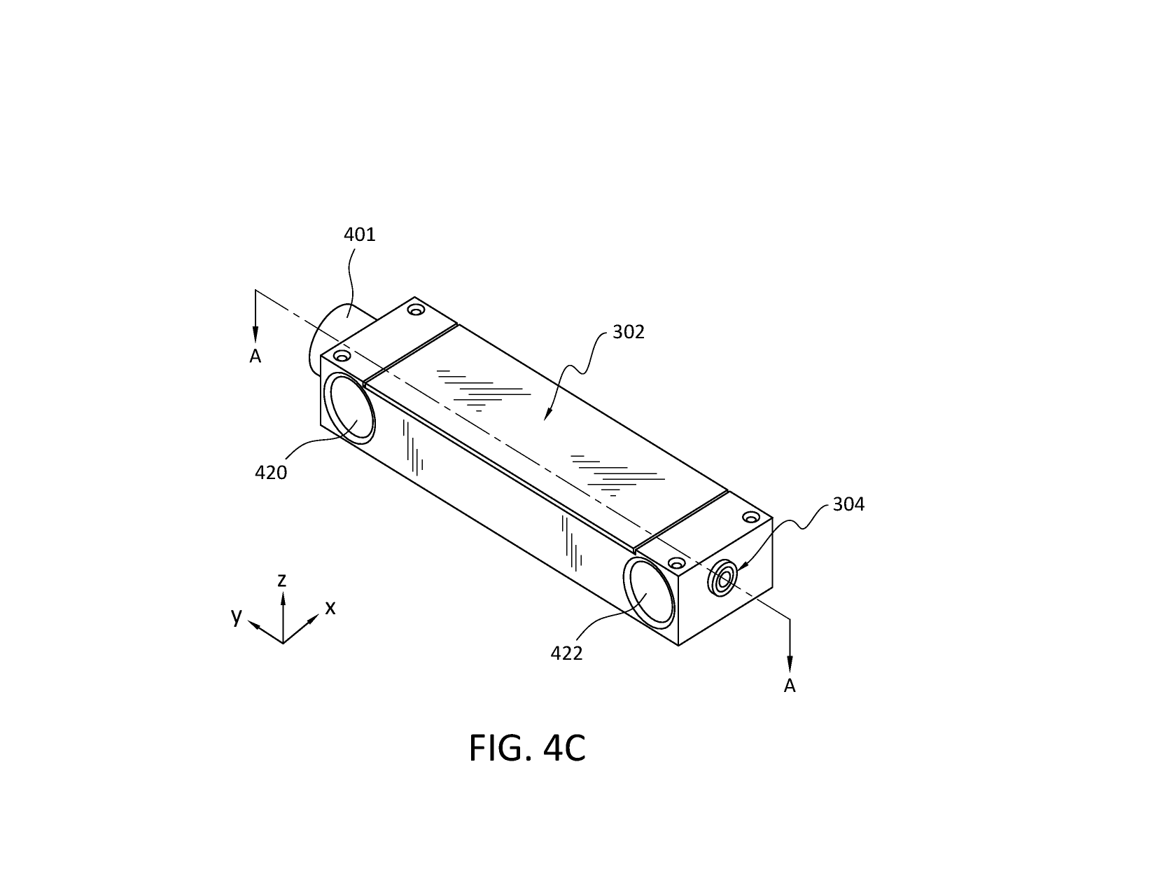

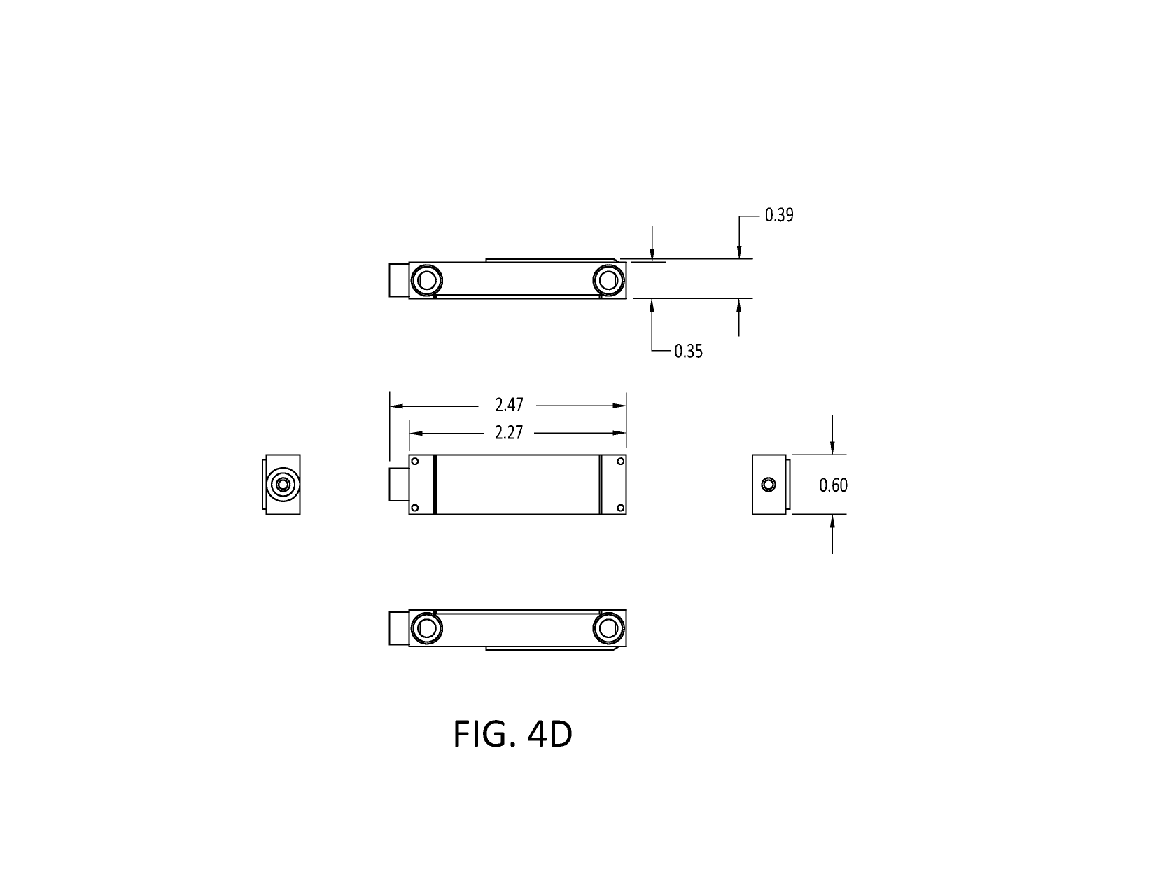

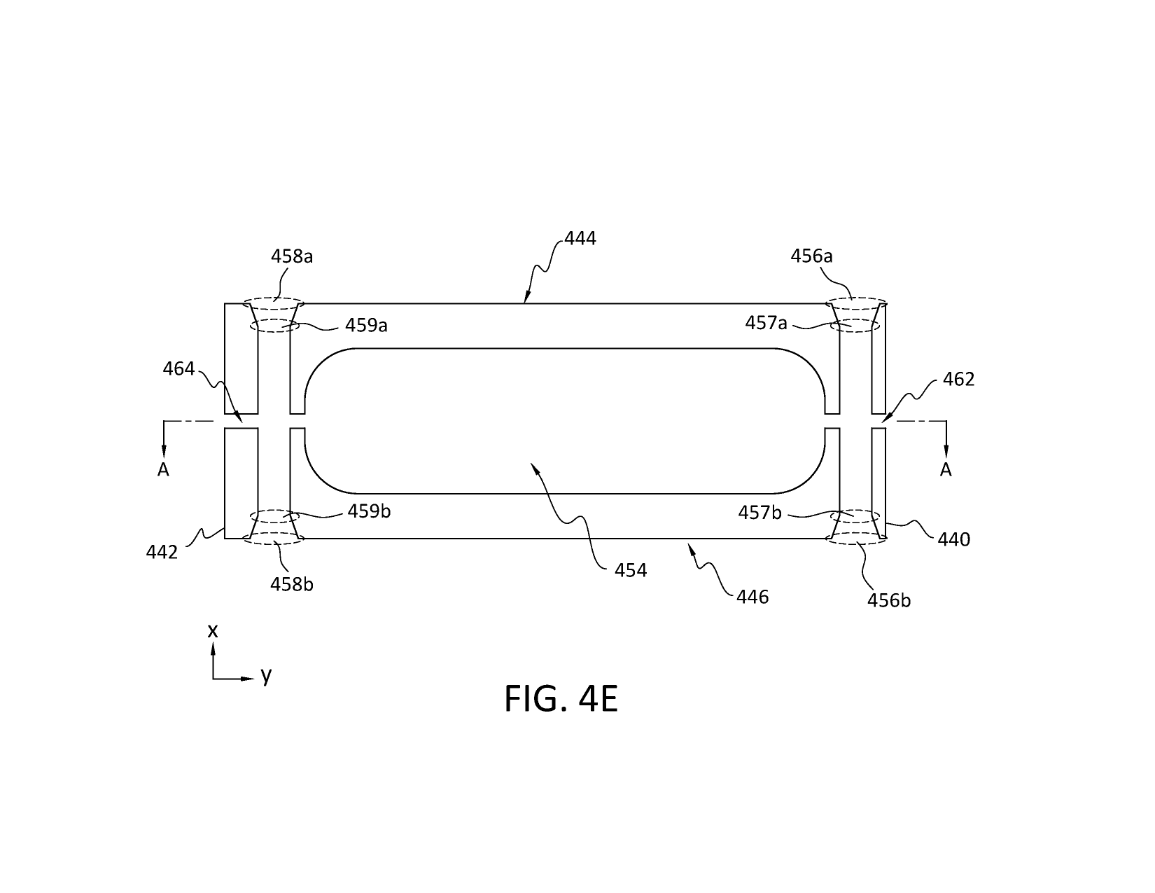

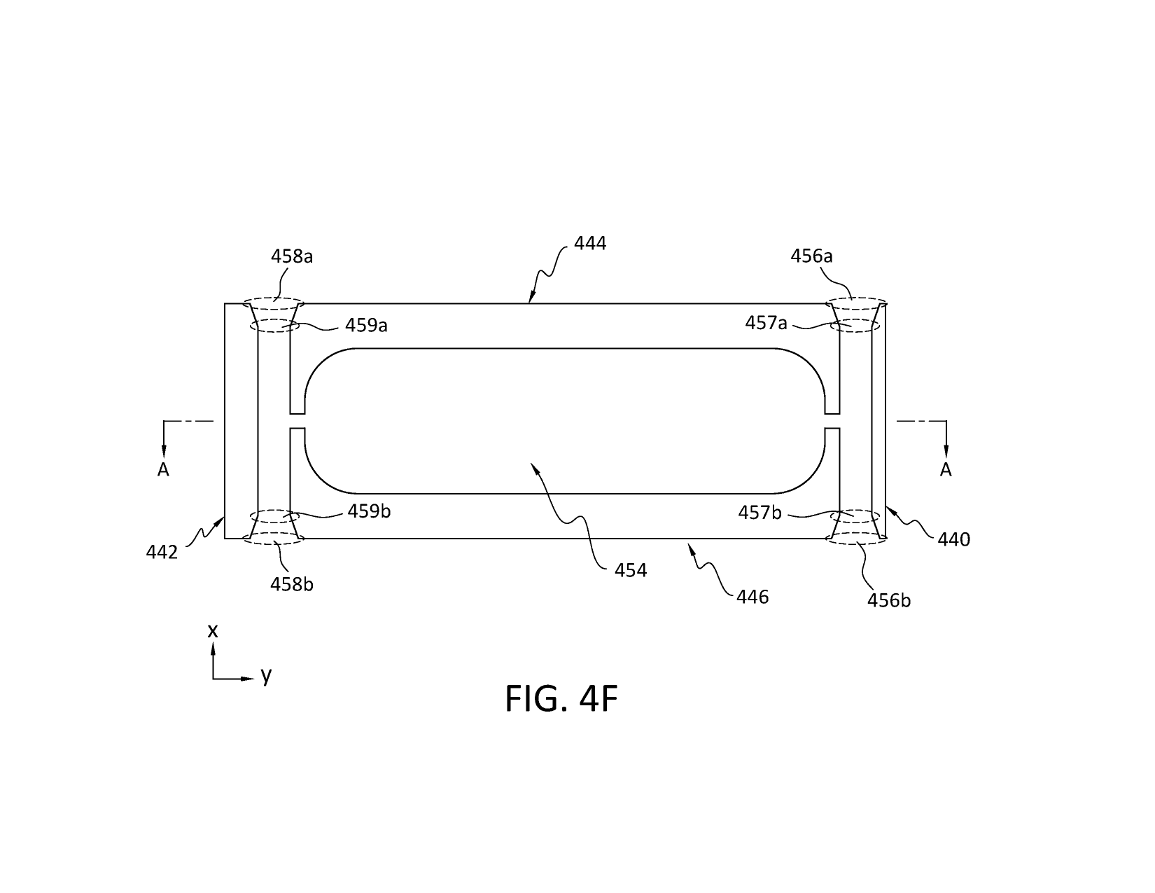

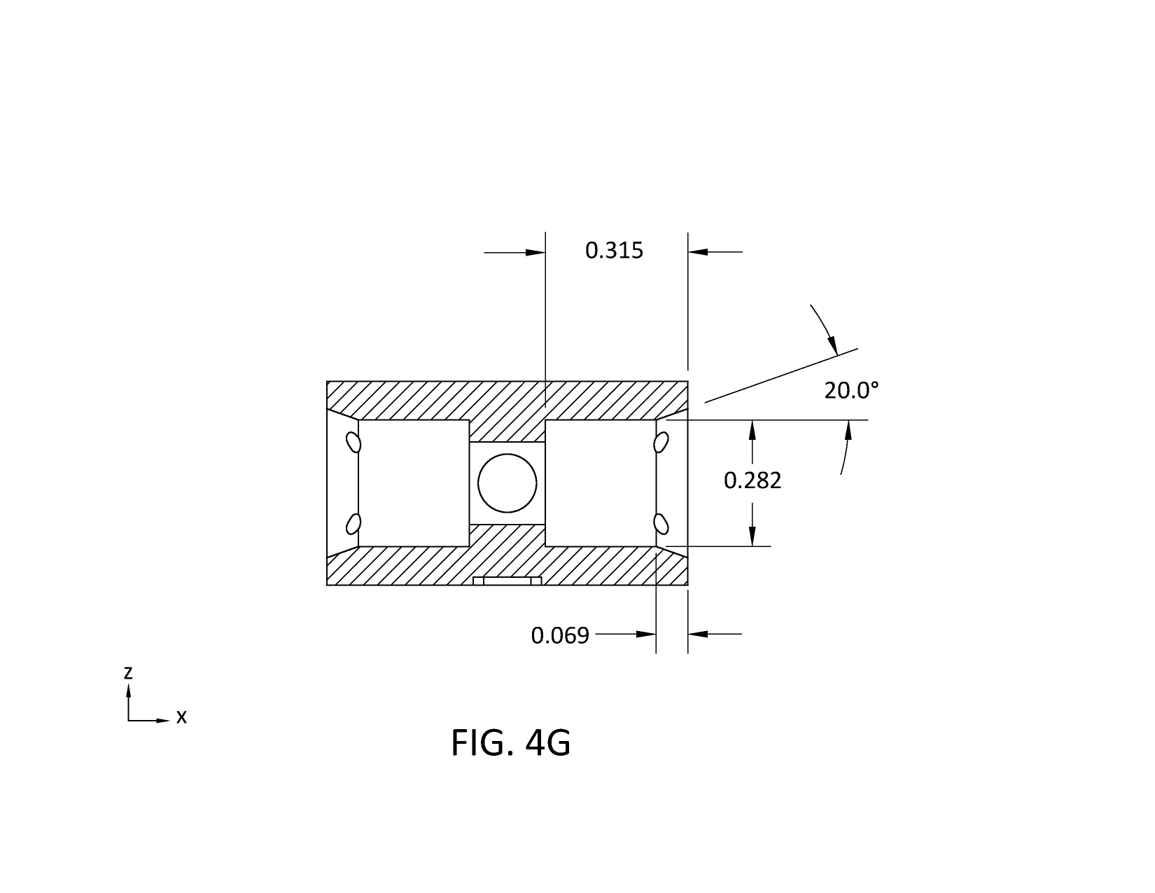

FIG. 4A is a perspective view of LCB 302, in accordance with this disclosure. In this view, a flange 401 on the backwall of LCB 302 is shown. In some embodiments, an I/O port is disposed on the backwall of LCB 302. However, in this perspective view, the backwall I/O port is not visible because it is obscured by flange 401.

FIG. 4B is an exploded perspective view of liquid-coolant-block 302, in accordance with this disclosure, showing an upper portion 402 of the liquid-coolant-block 302, a lower portion including a bottom side with a heat slug 404, and seals 406, 408 for preventing leakage of a coolant liquid from the assembled liquid-coolant-block 302, and screws 410 for ensuring that the bottom side with heat slug 404 is sealed tightly against upper portion 402.

FIG. 4C is a perspective view of an illustrative LCB 302 in accordance with this disclosure. In this view, set screw 304 is shown sealing the frontside I/O port, flange 401 is shown at the backside of LCB 302, and two sidewall I/O ports 420, 422 are shown.

FIG. 4D is a third angle projection of LCB 302, and provides dimensions (in inches) for an illustrative embodiment.

FIG. 4E is a cross-sectional view in the x-y plane of the LCB of FIG. 4C taken at the level of line A-A. FIG. 4E shows the LCB having a front side 440, a backside 442, a first sidewall 444, a second sidewall 446, and a main-enclosed-volume 454 (i.e., a cross-sectional view of the main internal cavity of the LCB). FIG. 4E further shows an outer-opening 456 a and an inner-opening 457 a of a first I/O port disposed on first sidewall 444; an outer-opening 456 b and an inner-opening 457 b of a second I/O port disposed on second sidewall 446; an outer-opening 458 a and an inner opening 459 a of a third I/O port disposed on first sidewall 444; and an outer-opening 458 b and an inner opening 459 b of a fourth I/O port disposed on second sidewall 446. FIG. 4E further shows a frontside I/O port 462 and a backside I/O port 464. Any of the first, second, third, fourth, frontside, and backside I/O ports of the LCB may act as either an inlet or outlet for a liquid coolant. The specific flow pattern may be determined by the arrangement of plugs, set screws, and LCB-connectors. That is, the LCB may support a variety of configurations depending on which I/O ports are open and which are closed. This allows a single LCB design to be used in multiple different arrangements for the flow of liquid coolant.

FIG. 4F is a cross-sectional view in the x-y plane of an alternative liquid-coolant-block in accordance with this disclosure. The LCB shown in FIG. 4F is similar to the LCB of FIG. 4E except that no frontside I/O port, and no backside I/O port are provided in this alternative embodiment. It is noted that the alternative LCB of FIG. 4F does not provide as many connection options as the LCB of FIG. 4E, however it may be less costly to manufacture.

FIG. 4G is a cross-sectional view, in the x-z plane, of an LCB, and shows an I/O port disposed on a first sidewall of the LCB and another I/O port disposed on a second sidewall of the LCB. FIG. 4G further provides nominal linear dimensions (in inches) and a nominal angle (in degrees). In particular, the nominal thickness of the LCB sidewall is shown and the nominal angle of the chamfer from the outside to the inside of the sidewall is shown. In this example, the dimensions of the two I/O ports are nominally the same.

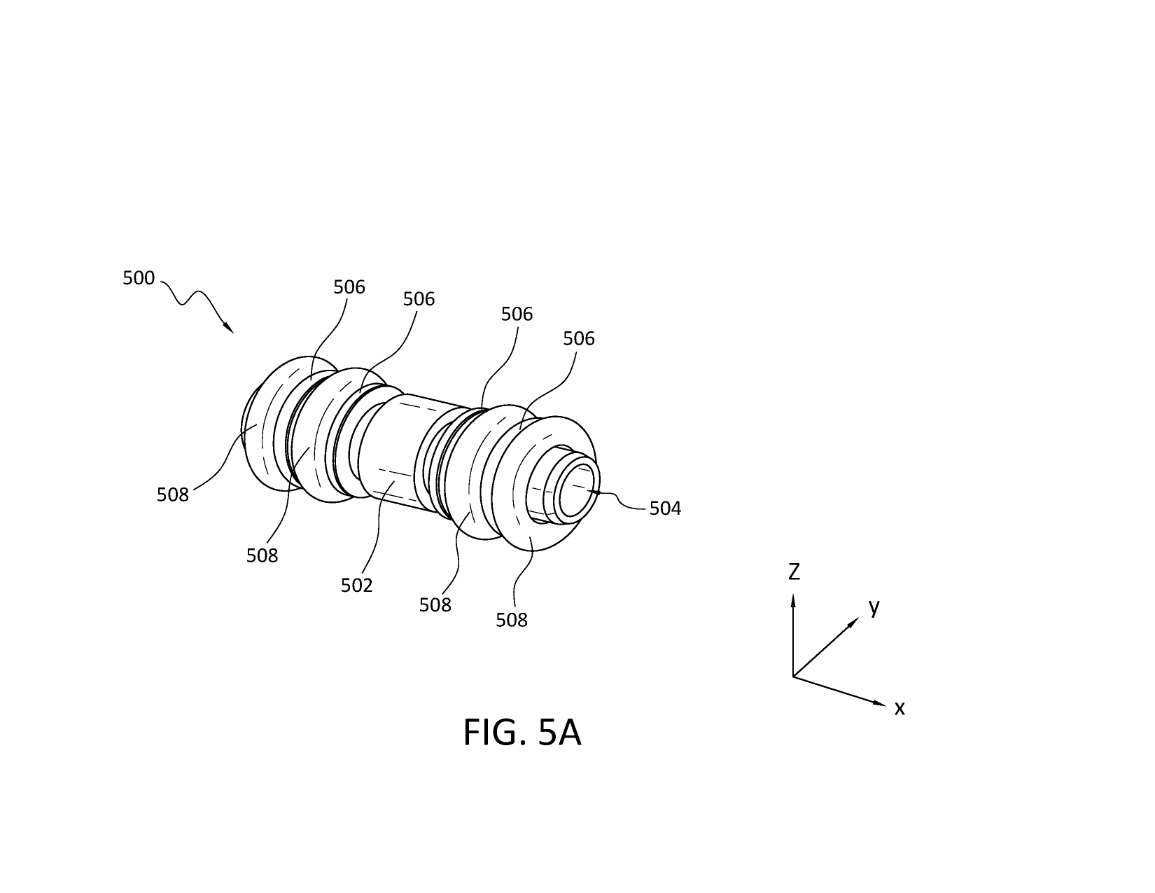

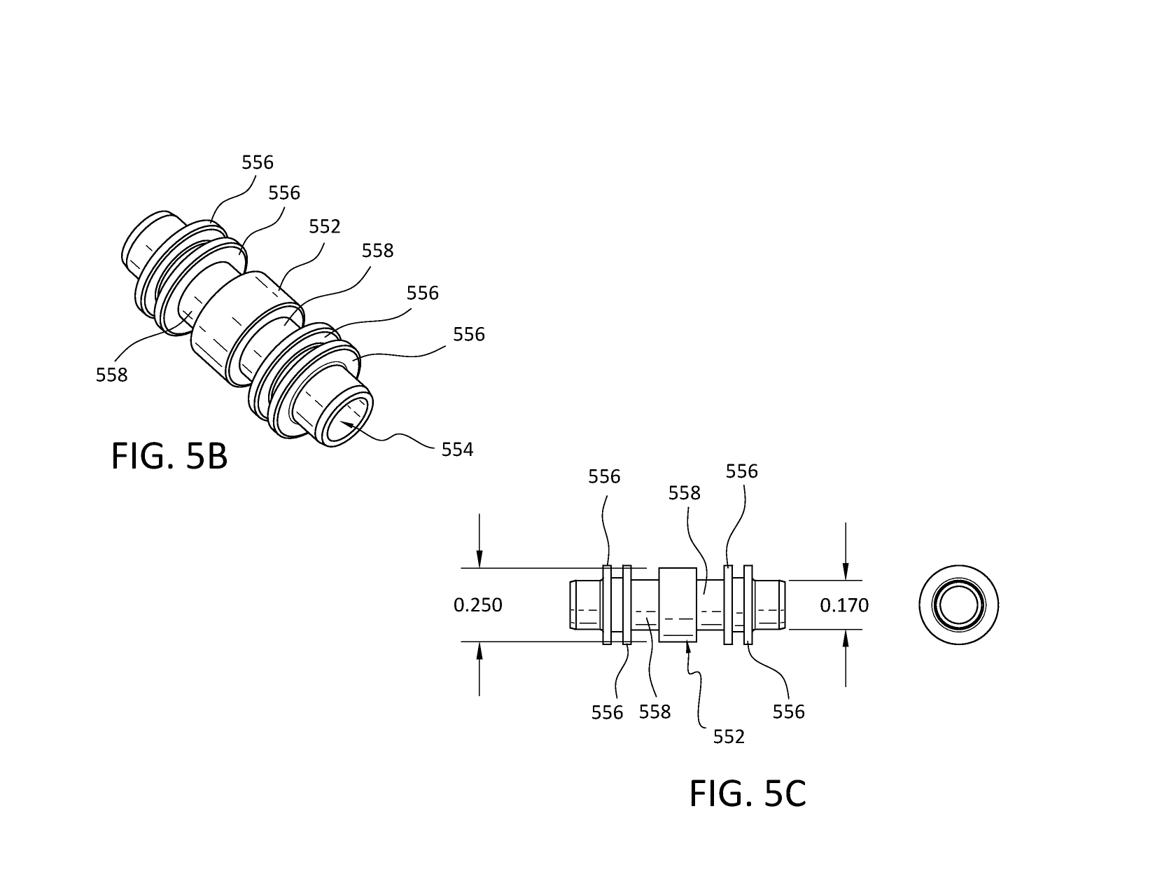

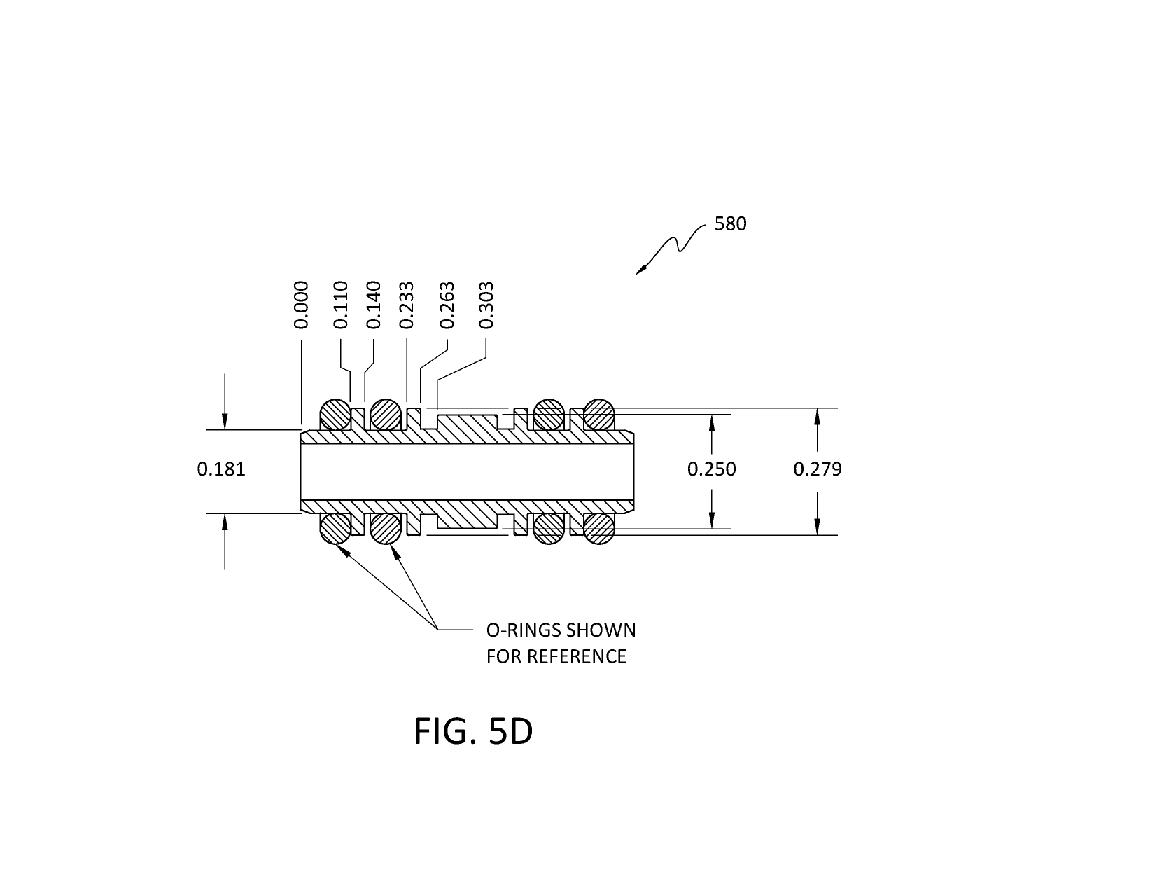

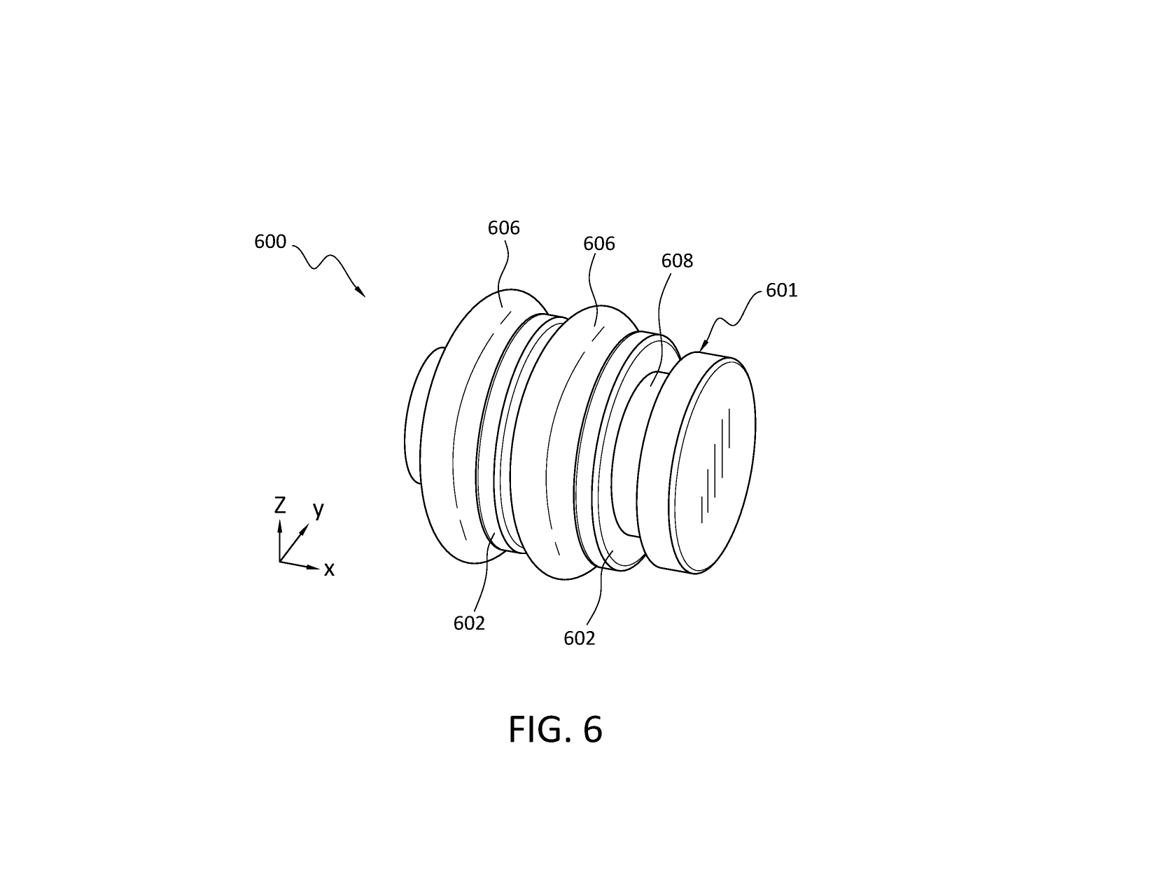

FIG. 5A is a perspective view of an LCB-connector 500 in accordance with this disclosure. LCB-connector 500 includes a tube portion 502 with a liquid flow path 504 therethrough. Tube portion 502 has a first end and a second end that is opposite its first end, and liquid flow path 504 is continuous between the first end and the second end. Tube portion 502 includes a plurality of circumferential tube-ridges 506 extending outwardly from the outer surface of tube portion 502. Each circumferential tube-ridge 506 is formed at a predetermined distance from the first and second ends of tube portion 502. FIG. 5A further shows a plurality of O-rings 508 disposed on the outer surface of tube portion 502. Each O-ring 508 is adjacent to at least one of the circumferential tube-ridges 506. LCB-connector 500 may be formed from a material or materials which are nominally impervious to liquid coolants that flow therethrough. Liquid coolants may include, but are not limited to, water, deionized water, and water-glycol mixtures (e.g., water and ethylene glycol, or water and propylene glycol). In various embodiments, LCB-connector 500 may provide a flow of liquid coolant between adjacent LCBs 302.

FIG. 5B is a perspective view of a tube portion 552 (i.e., without O-rings disposed thereon) of an LCB-connector in accordance with this disclosure. FIG. 5B indicates a liquid flow path 554 through tube portion 552, and circumferential tube-ridges 556 that extend outwardly from the outer surface of tube portion 552. FIG. 5B further shows grooves 558 that are configured to engage with a restraining pin that may be placed through an opening in the upper side of the LCB to prevent LCB-connector 500 from being pulled out.

FIG. 5C is a side view of the LCB-connector tube portion 552 shown in FIG. 5B. FIG. 5C includes dimensions (in inches) for an exemplary embodiment.

FIG. 5D is a cross-sectional view of FIG. 5C with O-rings added on the outer surface thereof, in accordance with this disclosure, and provides dimensions (in inches) for an exemplary embodiment.

FIG. 6 is a perspective view of a plug 600 in accordance with this disclosure, with O-rings disposed thereon. Plug 600 includes a plug body 601, at least one circumferential plug-ridge 602, and at least one O-ring 606. Exemplary plug 600 shown in FIG. 6 includes two circumferential plug-ridges 602, and two O-rings 606. Circumferential plug-ridges 602 extend outwardly from the surface of plug body 601. Plug 600 may be fitted into a sidewall I/O port of LCB 302. By fitting plug 600 into a sidewall I/O port, the flow of liquid coolant through that I/O port will be blocked. FIG. 6 further shows groove 608 that is configured to engage with a restraining pin that may be placed through an opening in the upper side of the LCB to prevent plug 600 from being pulled out.

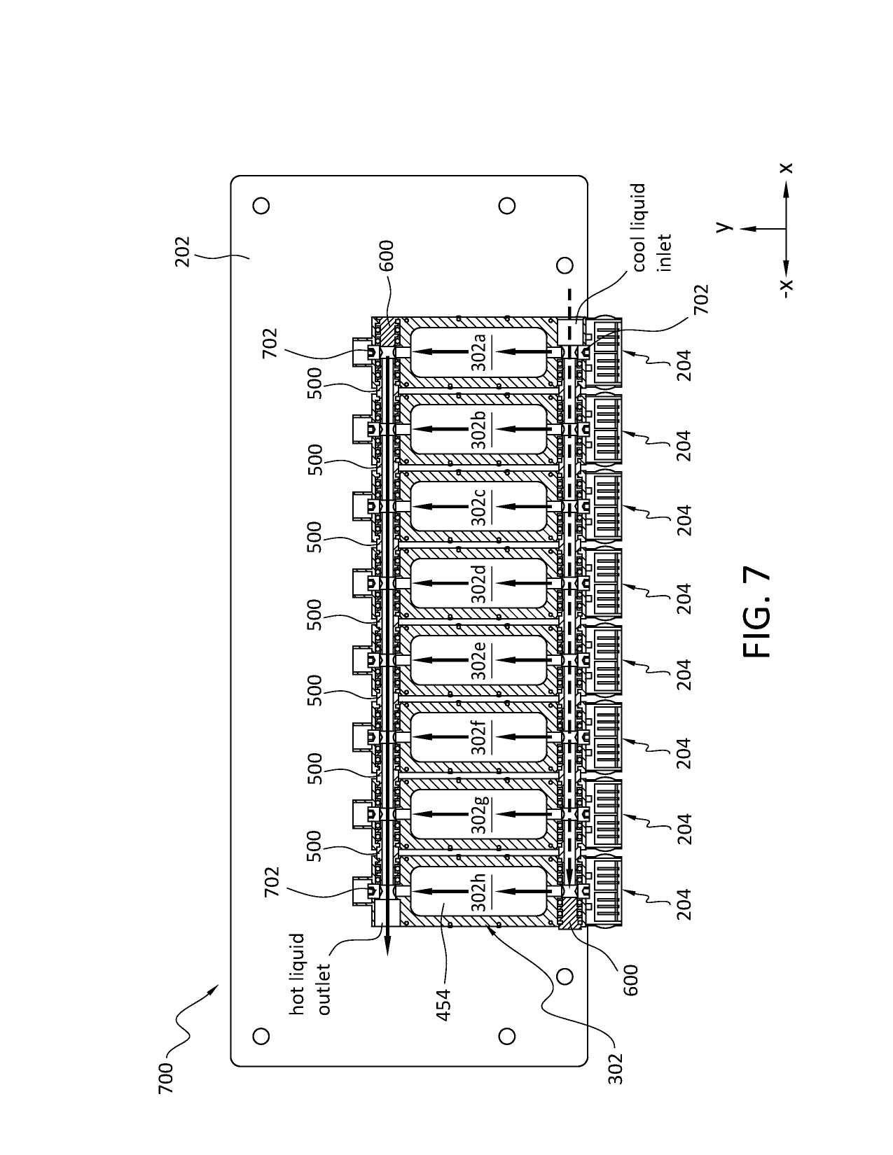

FIG. 7 is a top view of a liquid cooling arrangement wherein liquid-coolant-blocks are shown in a cross-sectional view through an x-y plane. FIG. 7 illustrates a cooling arrangement 700 in which the liquid-coolant-blocks 302, LCB-connectors 500, and plugs 600 are configured such that liquid coolant flows in parallel through LCBs 302. More particularly, a plurality of optical-module-cages 204 are attached to substrate 202, which may be, but is not limited to, a printed circuit board. Each optical-module-cage 204 has an LCB 302 disposed on a topside thereof. In this illustrative embodiment there are eight LCBs 302a, 302b, 302c, 302d, 302e, 302f, 302g and 302h. Alternative embodiments may have more or fewer LCBs.

To achieve the configuration mentioned above wherein liquid coolant flows in parallel through LCBs 302 the following arrangement of set screws, LCB-connectors, and plugs may be used. Referring to FIGS. 7, 4D, and 4E, each LCB 302 has an I/O port 462 disposed on a front side 440 thereof, wherein the frontside I/O port 462 is sealed by set screw 702. Likewise, in this embodiment, each LCB 302 has an I/O port 464 disposed on a back side thereof, wherein the backside I/O port 464 is sealed by set screw 702. Further, each LCB 302 has a first sidewall 444 and a second sidewall 446, and each of those sidewalls has two I/O ports disposed thereon.

In the configuration of FIG. 7, a first LCB 302a is arranged such that its first I/O port is coupled to receive cool liquid (e.g., from a coolant distribution unit (CDU)), its third I/O port is plugged by plug 600, its frontside I/O port is plugged by a set screw 702, its backside I/O port is plugged by another set screw 702, its second I/O port and its fourth I/O port are coupled, respectively, to the first I/O port and the third I/O port of second LCB 302b by LCB-connectors 500. This configuration allows the cool liquid to enter from the first I/O port of LCB 302a and flow in two directions. The first direction (negative x-direction in FIG. 7) is through the second I/O port of LCB 302a, through an LCB-connector, and into the first I/O port of LCB 302b. The second direction (y-direction in FIG. 7) is from the frontside of LCB 302a toward the backside of LCB 302a. As the cool liquid moves in the second direction, heat from an underlying optical transceiver module is transferred to the liquid.

It is noted that coolant distribution units are commercially available and provide the functions of a cooler and a pump.

Still referring to FIG. 7, the configurations of LCBs 302b, 302c, 302d, 302e, 302f, and 302g are the same. That is, for a given one of the aforementioned LCBs, the frontside I/O port is plugged with a set screw, the backside I/O port is plugged with a set screw, the first I/O port is coupled by an LCB-connector to the second I/O port of the previous LCB, the second I/O port is coupled by an LCB-connector to the first I/O port of the next LCB, the third I/O port is coupled by an LCB-connector to the fourth I/O port of the previous LCB, and the fourth I/O port is coupled by an LCB-connector to the third I/O port of the next LCB. In this way each of LCBs 302b, 302c, 302d, 302e, 302f, and 302g receive cool liquid via their respective first I/O ports, and pass cool liquid through their respective second I/O ports to the next LCB. And, in this way, the heated liquid passes out of the respective fourth I/O ports into the third I/O port of next LCB.

Still referring to FIG. 7, the configuration of LCB 302 h is slightly different than the configuration of the other LCBs of FIG. 7. LCB 302 h receives cool liquid through its first I/O port, but its second I/O port is plugged by a plug 600. LCB 302 h receives heated liquid through its third I/O port but does not require an LCB-connector in its fourth I/O port because the fourth I/O port of LCB 302 h acts as a hot liquid outlet.

Although FIG. 7 illustrates an embodiment in which cool liquid moves in the negative x-direction along the frontside of the LCBs, and the heated liquid moves in the negative x-direction along the backside of the LCBs, alternative implementations in accordance with this disclosure may provide cool liquid and heated liquid moving in the positive x-direction; or other alternative implementations may provide for the heated liquid moving along the frontside of the LCBs and cool liquid running along the backside of the LCBs. In some embodiments, running the cool liquid along the backside of the LCBs may expand the cooling shadow of the LCBs and therefore provide additional cooling capacity in an area further into the interior of the system in which this cooling arrangement is used. Likewise running the heated liquid along the frontside of the LCBs may allow part of the system housing, e.g., the front panel, to act as a secondary heat sink.

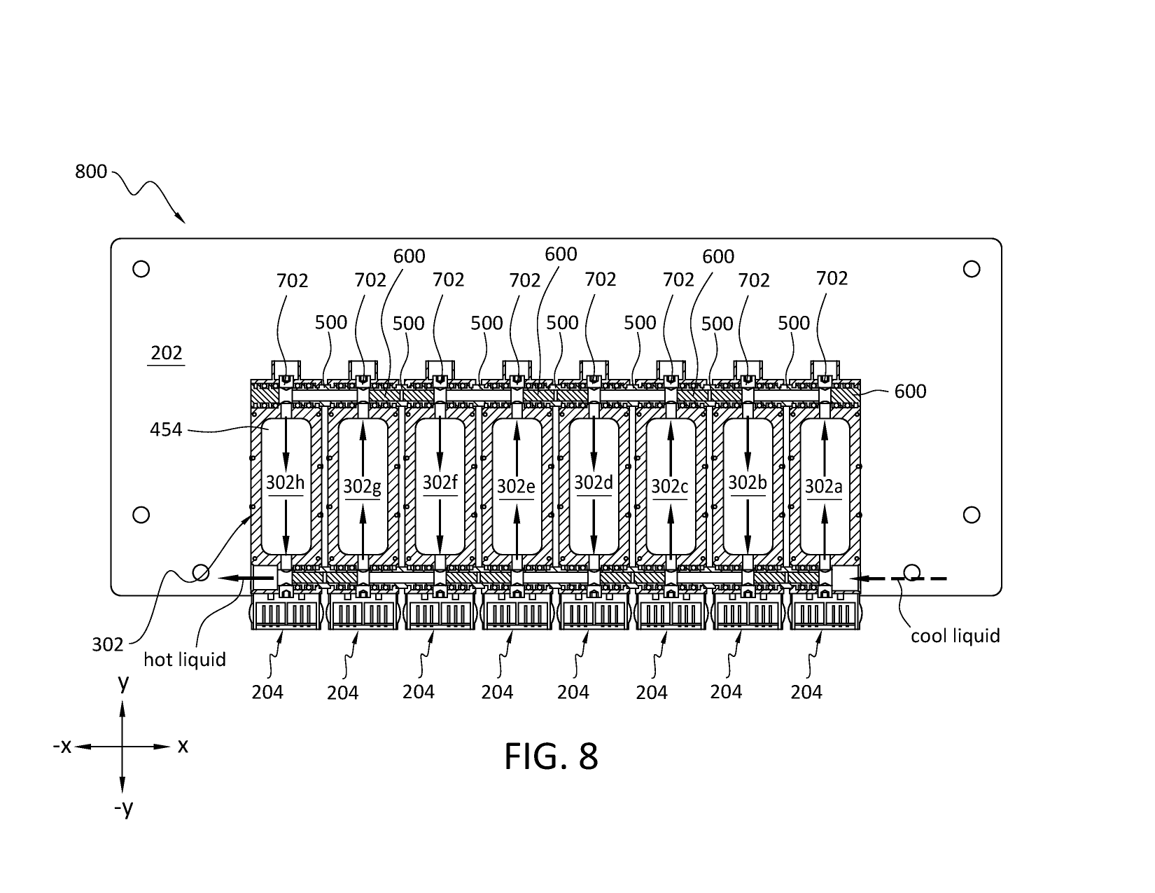

FIG. 8 is a top view of a liquid cooling arrangement wherein liquid-coolant-blocks are shown in a cross-sectional view through an x-y plane. FIG. 8 illustrates a cooling arrangement 800 in which the liquid-coolant-blocks 302, LCB-connectors 500, plugs 600, and set screws 702 are configured such that liquid coolant flows serially through LCBs 302. Unlike the parallel fluid flow shown in FIG. 7, where the cool liquid enters from the frontside and the heated liquid exits from the backside in each LCB, the serial fluid flow shown in FIG. 8 moves in both the positive and negative y-directions.

In cooling arrangement 800, the first I/O port of LCB 302 a is an inlet for receiving cool liquid. The frontside I/O port and the backside I/O port of LCB 302 a are respectively plugged by set screws 702. The second and third I/O ports of LCB 302 a are respectively plugged by plugs 600. In operation, liquid coolant passes through LCB 302 a in the positive y-direction and exits in the negative x-direction through the fourth I/O port of LCB 302a.

Still referring to FIG. 8, LCB 302b is configured such that its frontside I/O port is plugged by a set screw 702, its backside I/O port is plugged by another set screw 702, its first I/O port is plugged by a plug 600, its second I/O port is coupled to an LCB-connector 500 for fluid communication with the first I/O port of the next LCB, its third I/O port is coupled to an LCB-connector 500 for fluid communication with the fourth I/O port of the previous LCB, and its fourth I/O port is plugged by a plug 600. LCBs 302 d and 302 f are each configured in the same way as LCB 302 b.

Still referring to FIG. 8, LCB 302c is configured such that its frontside I/O port is plugged by a set screw 702, its backside I/O port is plugged by another set screw 702, its first I/O port is coupled to an LCB-connector to receive fluid from the second I/O port of the previous LCB, its second I/O port is plugged by a plug 600, its third I/O port is plugged by a plug 600, and its fourth I/O port is coupled to an LCB-connector for fluid communication with the next LCB. LCBs 302 e and 302 g are each configured in the same way as LCB 302 c.

Still referring to FIG. 8, LCB 302 h is configured such that its frontside I/O port is plugged by a set screw 702, its backside I/O port is plugged by another set screw 702, its first I/O port is plugged by a plug 600, its second I/O port as an outlet for the hot liquid, its third I/O port is coupled to an LCB-connector for fluid communication with the fourth I/O port of the previous LCB, and its fourth I/O port is plugged by a plug 600.

Although the illustrative cooling arrangement 800 shows the cooling liquid moving in a serpentine path and generally progressing in the negative x-direction, it will be appreciated that in alternative arrangements the cooling liquid may enter through the third I/O port of LCB 302h, move in a serpentine path, and progress generally in the positive x-direction, and exit through the first I/O port of LCB 302a.

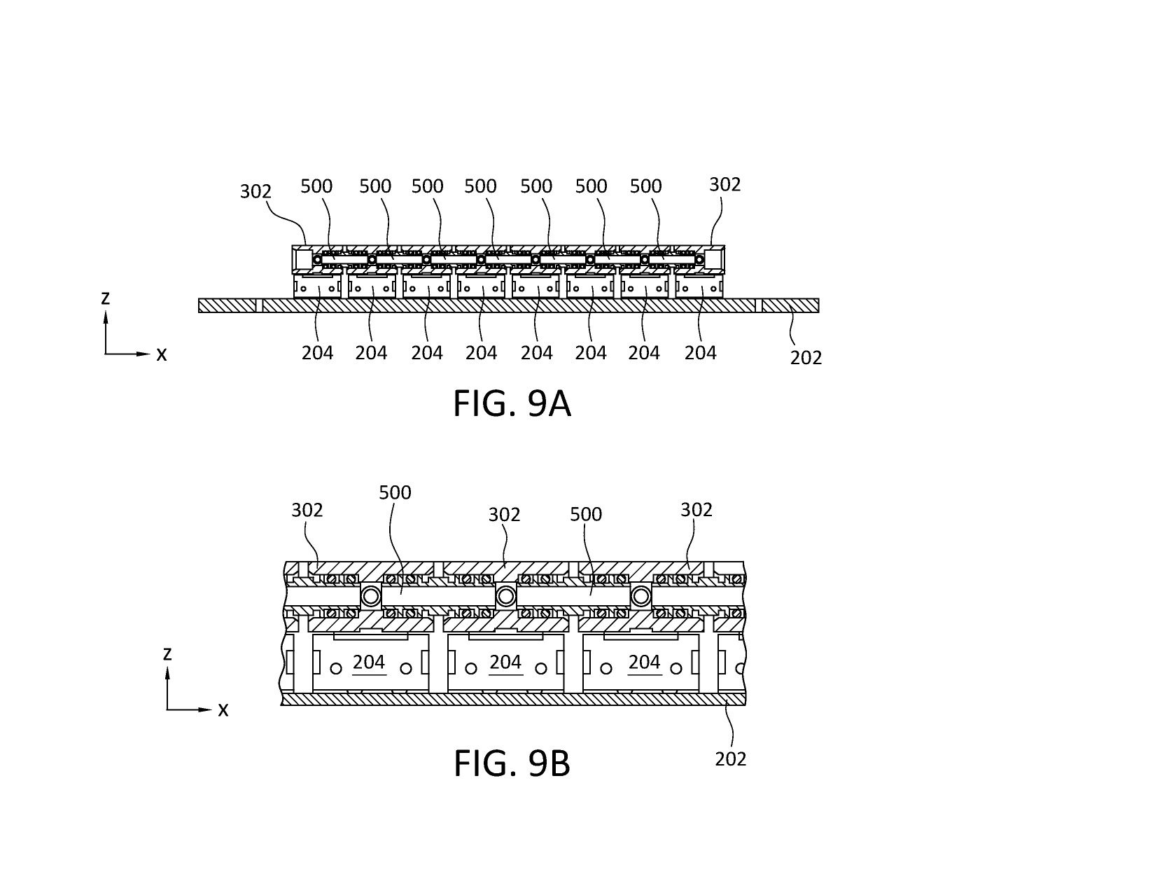

FIG. 9A shows a vertical cross-section of the illustrative embodiment of FIG. 7. FIG. 9A illustrate a plurality of optical-module-cages 204 disposed on substrate 202. Substrate 202 may be, but is not limited to, a printed circuit board, and optical-module-cages 204 may be attached to the printed circuit board. Each optical-module-cage 204 is shown to a corresponding LCB 302 disposed thereover. In some embodiments a resilient biasing element, such as but not limited to, a spring may be included to maintain the LCBs in in contact with the optical-module-cages 204 and/or with optical transceiver modules (not shown in FIG. 9A) that may be inserted into the optical-module-cages 204. FIG. 9A further shows LCB-connectors 500 coupling the LCBs 302 to each other to provide a fluid communication path therebetween.

FIG. 9B is an enlarged view of a portion of FIG. 9A.

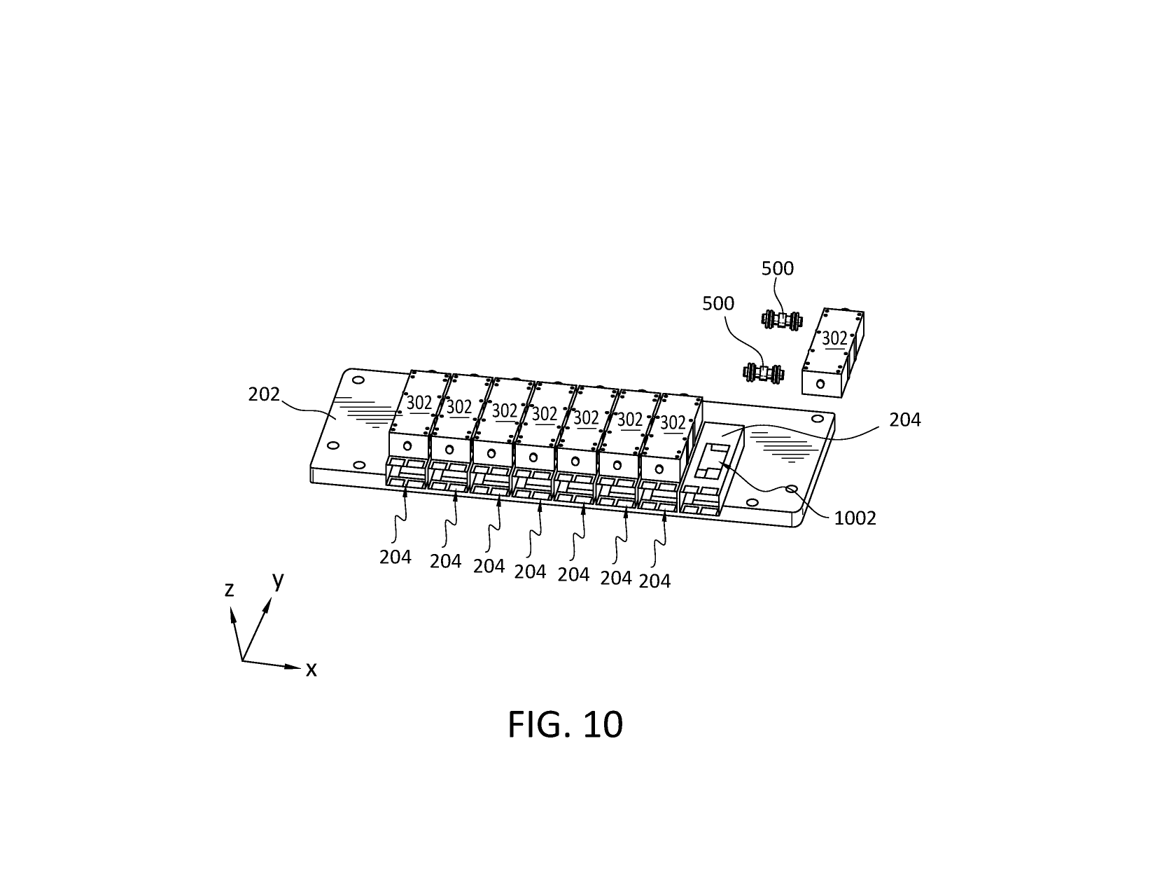

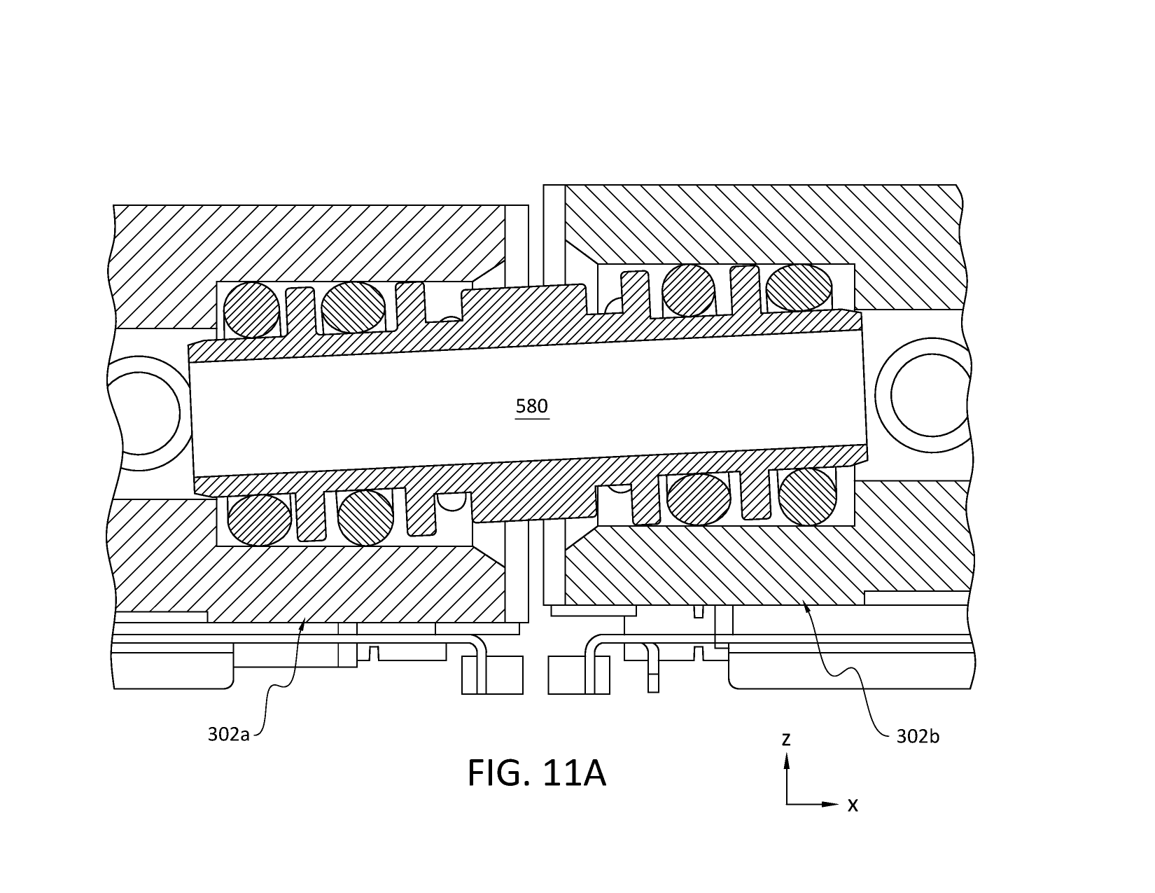

FIG. 10 is a partially exploded perspective view illustrating liquid-coolant-blocks 302 disposed on optical-module-cages 204 and coupled for the flow of liquid coolant by liquid-coolant-block-connectors 500, in accordance with this disclosure. The optical-module-cages 204 are attached to substrate 202. Substrate 202 may be, but is not limited to, a printed circuit board. FIG. 10 further illustrates an opening 1002 in the topside of an optical-module-cage 204. Opening 1002 allows LCB 302 to make effective thermal contact with an optical transceiver module (not shown in FIG. 10) when that module is inserted into the optical-module-cage 204.

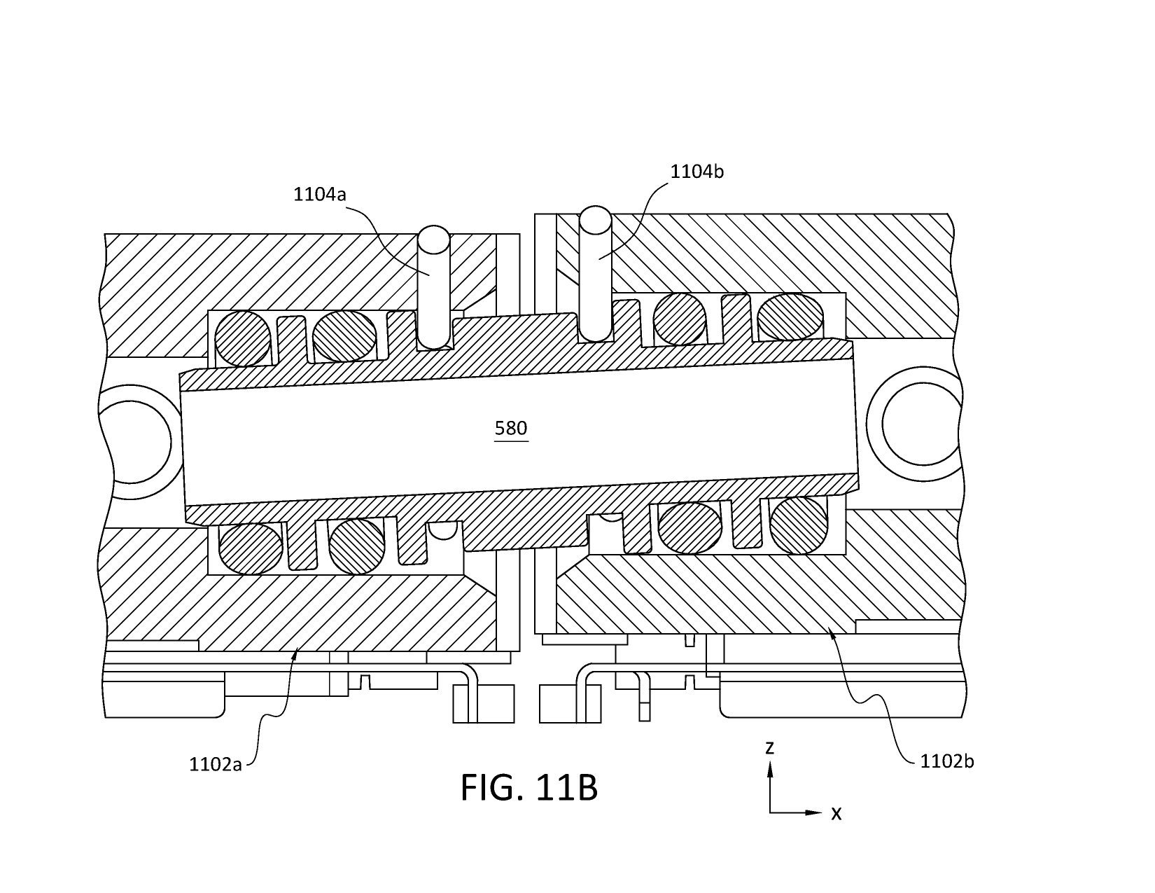

FIG. 11A is a cross-sectional view of adjacent liquid-coolant-blocks coupled by a liquid-coolant-block-connector, where one of the liquid-coolant-blocks is vertically offset with respect to the other liquid-coolant-block. Although FIG. 11A shows a first LCB 302a and a second LCB 302b that is vertically offset relative to first LCB 302a, it will be appreciated that in the operation of some embodiments there may be some component of lateral displacement of second LCB 302b relative to first LCB 302a. The general term for such relative movement, or displacement, is referred to herein as angular displacement.

FIG. 11A shows first LCB 302 a, second LCB 302 b, and an LCB-connector 580 coupled between first LCB 302 a and second LCB 302 b. Second LCB 302 b is offset in the z-direction relative to LCB 302 a, resulting in a cant by LCB-connector 580. However it can be seen that LCB-connector 580 maintains, even when LCB 302 b is vertically offset, a leak-proof seal.

FIG. 11B is similar to FIG. 11A, but further shows how retaining pins may be used to prevent the LCBs that are connected by an LCB-connector from coming apart. FIG. 11B shows a first LCB 1102 a, a second LCB 1102 b, and an LCB-connector 580 coupled between first LCB 1102 a and second LCB 1102 b. Second LCB 1102 b is offset in the z-direction relative to first LCB 1102 a, resulting in a cant by LCB-connector 580. However it can be seen that LCB-connector 580 maintains, even in when LCB 302 b is vertically offset, a leak-proof seal. FIG. 11B shows a first retaining pin 1104a that passes through an opening in an upper side of first LCB 1102a, and engages with a first annular groove of LCB-connector 580, and also shows a second retaining pin 1104b that passes through an opening in an upper side of second LCB 1102b, and engages with a second annular groove of LCB-connector 580. In this way, LCBs that are connected by an LCB-connector may be prevented from coming apart.

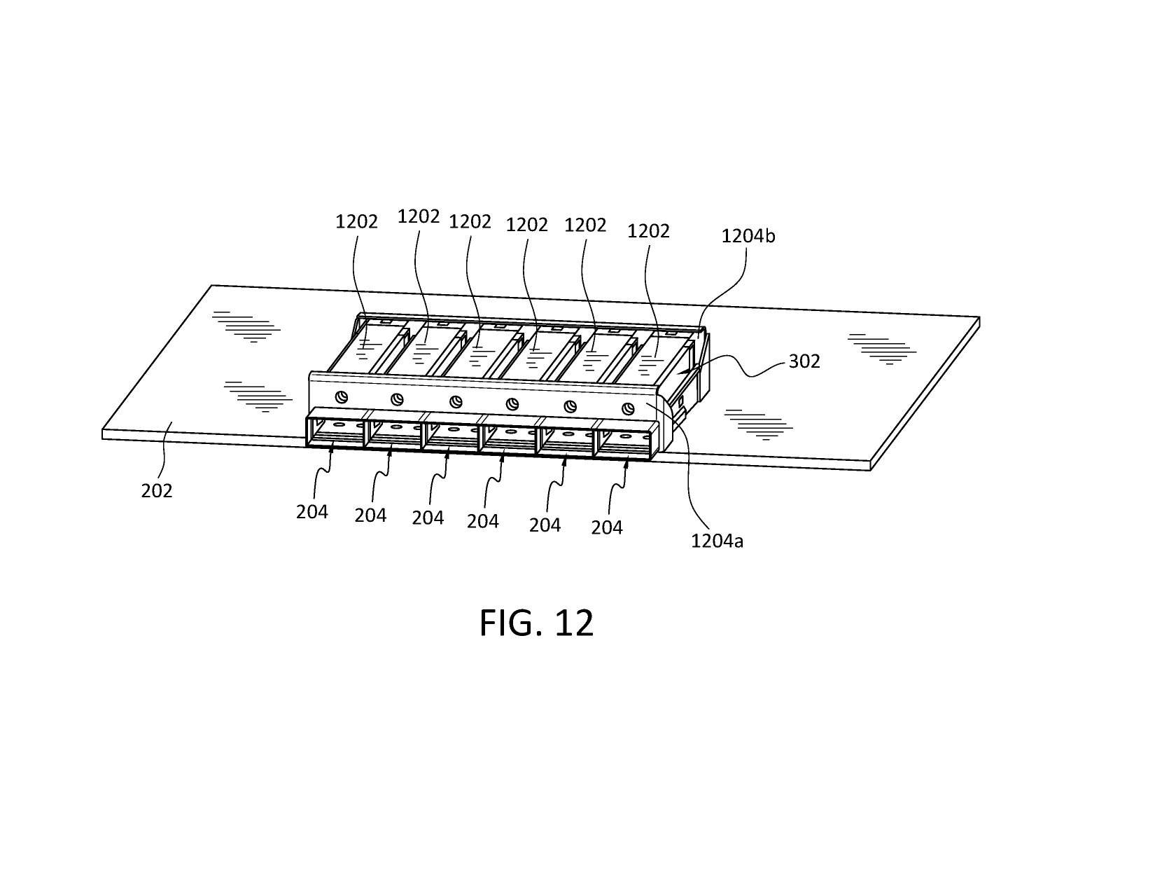

FIG. 12 is a perspective view of an embodiment, in accordance with this disclosure, that includes resilient biasing elements, and brackets to hold those resilient biasing elements in place. FIG. 12 shows a plurality of optical-module-cages 204 disposed on substrate 202. Substrate 202 may be, but is not limited to a printed circuit board, and optical-module-cages 204 may be attached to the printed circuit board. Each optical-module-cage 204 has a corresponding liquid-coolant-block 302 disposed thereover. In accordance with this disclosure, a resilient biasing element 1202 is disposed over each liquid-coolant-block 302. Resilient biasing elements may be, but are not limited to leaf springs. Resilient biasing elements may be held in place by brackets 1204a and 1204b as shown in FIG. 12.

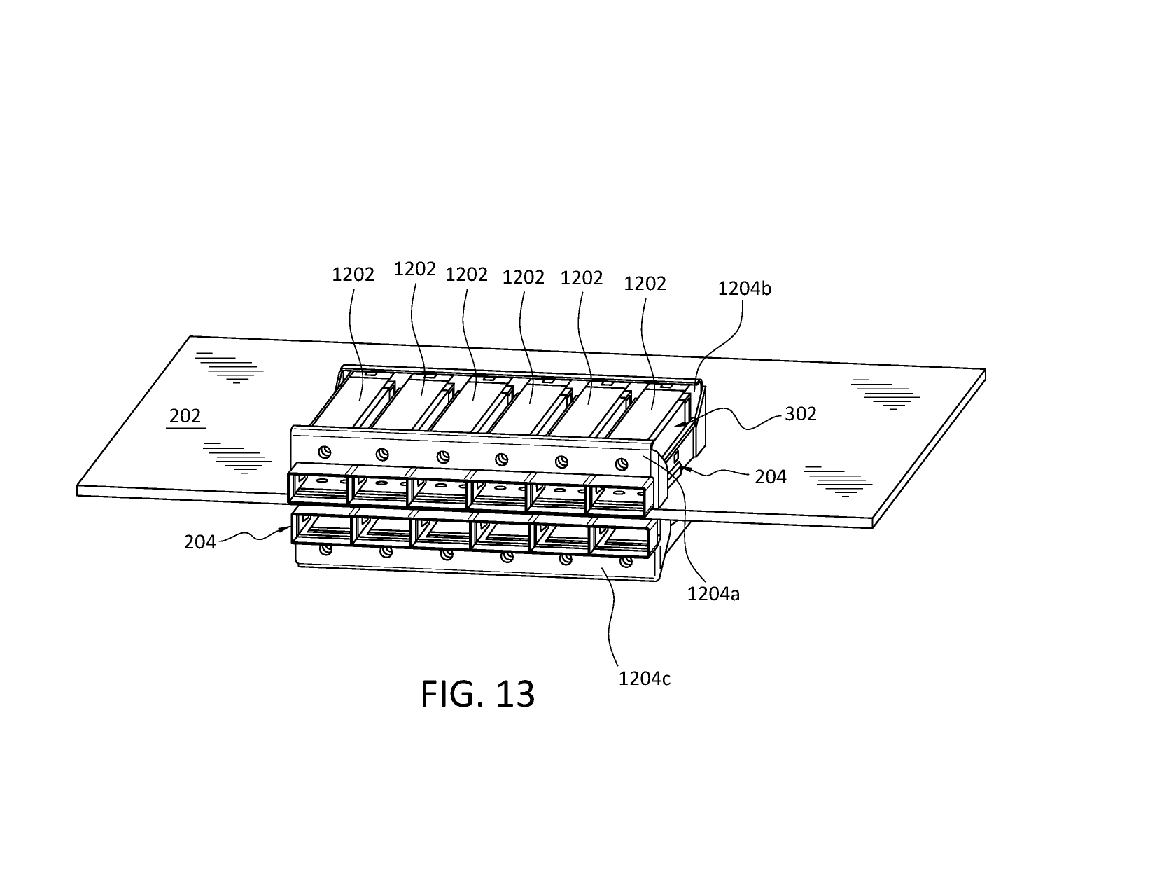

FIG. 13 is a perspective view of an embodiment, in accordance with this disclosure, that provides a belly-to-belly arrangement for multiple rows of optical-module-cages. The illustrative embodiment of FIG. 13 is similar to the embodiment shown in FIG. 12 except with an additional set of optical-module-cages 204, liquid-coolant-blocks 302, and resilient biasing elements 1202 all disposed on an underside of substrate 202. The underside resilient biasing elements are held in place with brackets in the same way that the topside resilient biasing elements 1202 are held in place. Bracket 1204c is equivalent to bracket 1204a. A bracket equivalent to bracket 1204b may also be used to secure the underside resilient biasing elements (but that portion of the underside structural elements is not visible in this figure).

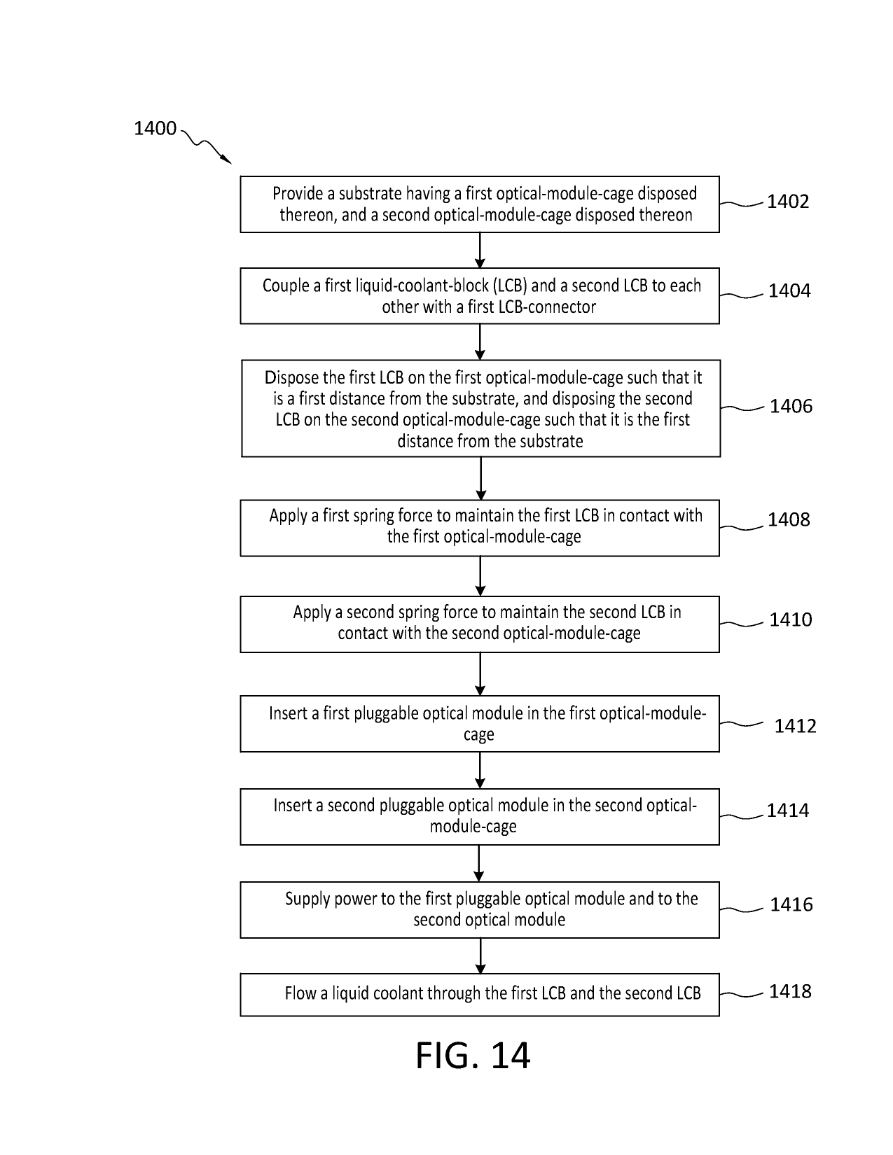

FIG. 14 is a flow diagram of a method 1400 of removing heat from a plurality of optical modules, in accordance with this disclosure. Method 1400 includes providing 1402 a substrate having a first optical-module-cage disposed thereon, and a second optical-module-cage disposed thereon, coupling 1404 a first LCB and a second LCB to each other with a first LCB-connector, and disposing 1406 the first LCB on the first optical-module-cage such that it is a first distance from the substrate, and disposing the second LCB on the second optical-module-cage such that it is also the first distance from the substrate. Method 1400 further includes applying 1408 a first spring force to maintain the first LCB in contact with the first optical-module-cage, applying 1410 a second spring force to maintain the second LCB in contact with the second optical-module-cage, inserting 1412 a first pluggable optical module in the first optical-module-cage, inserting 1414 a second pluggable optical module in the second optical-module-cage, and supplying 1416 power to the first pluggable optical module and to the second optical module. Method 1400 further includes flowing 1418 a liquid coolant through the first LCB and the second LCB. The first LCB and the second LCB may be configured such that liquid coolant flows through them in parallel. Alternatively, the first LCB and the second LCB may be configured such that liquid coolant flows through them serially. In various embodiments, a commercially-available coolant distribution unit may be used for cooling and pumping the liquid coolant. In various embodiments of the method 1400 of removing heat from a plurality of optical modules, the liquid coolant may be selected from a variety of coolant liquids including but not limited to water, deionized water, and water-glycol mixtures (e.g., water and ethylene glycol, or water and propylene glycol).

In other embodiments, in accordance with this disclosure, an apparatus in accordance with this disclosure includes a substrate, a first optical-module-cage attached to the substrate, and a second optical-module-cage attached to the substrate, wherein the second optical-module-cage is nominally parallel to the first optical-module-cage, and spaced a first distance away from the first optical-module-cage. The substrate may be, but is not limited to, a printed circuit board. The first and second optical-module-cages are configured to receive a pluggable optical module. The pluggable optical module may be, but is not limited to, an optical transceiver. The pluggable optical module may be, but is not limited to, a small form-factor pluggable (SFP) module. The apparatus may further have a plurality of liquid-coolant-blocks that each have a top side, a bottom side, a front side, a back side, a right side, and a left side, wherein each top side is configured to engage with a resilient biasing element, each bottom side includes a heat slug, each front side has a front-side-opening therein, each back-side has a back-side-opening therein, each right side has at least two inlet/outlet ports, and each left side has at least two inlet/outlet ports. The front-side-opening may be sealed or plugged with, for example, a set screw or a plug. Likewise, the back-side-opening may be sealed or plugged with, for example, a set screw or a plug. The resilient biasing element is configured to provide a force that acts to hold a liquid-coolant-block onto an underlying optical-module-cage to promote effective heat transfer between an optical module inserted in the optical-module-cage and the liquid-coolant-block.

According to an aspect of this disclosure, a liquid-coolant-block (LCB) includes a housing defining a main-enclosed-volume, a first liquid-transport-path coupled to the main-enclosed-volume, and a second liquid-transport-path coupled to the main-enclosed-volume, wherein the housing includes a first sidewall and a second sidewall, a first inlet/outlet (I/O) port disposed on the first sidewall and coupled to the first liquid-transport-path, a second I/O port disposed on the second sidewall and coupled to the first liquid-transport-path, a third I/O port disposed on the first sidewall and coupled to the second liquid-transport-path, and a fourth I/O port disposed on the second sidewall and coupled to the second liquid-transport-path, wherein the first I/O port includes a first outer-opening having a first outer-opening-diameter at an outer surface of the first sidewall and a first inner-opening disposed inwardly from the first outer-opening, the first inner-opening having a first inner-opening-diameter that is less than the first outer-opening-diameter, the first sidewall is chamfered between the first outer-opening and the first inner-opening, the third I/O port includes a third outer-opening having a third outer-opening-diameter at an outer surface of the first sidewall, and a third inner-opening disposed inwardly from the third outer-opening, the third inner-opening having a third inner-opening-diameter that is less than the third outer-opening-diameter, and the first sidewall is chamfered between the third outer-opening and the third inner-opening, the first I/O port is configured to receive a first portion of a first LCB-connector that further has a second portion that is engaged with a second LCB, and the third I/O port is configured to receive a first portion of a second LCB-connector that further has a second portion that is engaged with the second LCB.

In some embodiments, a first chamfer between the first inner-opening and the first outer-opening is nominally 20 degrees, a third chamfer between the third inner-opening and the third outer-opening is nominally 20 degrees, the second I/O port includes a second outer-opening having a second outer-opening-diameter at an outer surface of the second sidewall, and a second inner-opening disposed inwardly from the second outer-opening, the second inner-opening having a second inner-opening-diameter that is less than the second outer-opening-diameter, and the second sidewall is chamfered between the first outer-opening and the first inner-opening, and the fourth I/O port includes a fourth outer-opening having a fourth outer-opening diameter at an outer surface of the second sidewall, and a fourth inner-opening disposed inwardly from the fourth outer-opening, the fourth inner-opening having a fourth inner-opening-diameter that is less than the fourth outer-opening-diameter, and the second sidewall is chamfered between the fourth outer-opening and the fourth inner-opening.

In some embodiments, a second chamfer between the second inner-opening and the second outer-opening is nominally 20 degrees, a fourth chamfer between the fourth inner-opening and the fourth outer-opening is nominally 20 degrees, and the first outer-opening-diameter, and the second outer-opening-diameter are nominally the same, and the third outer-opening-diameter, and the fourth outer-opening-diameter are nominally the same.

In some embodiments, the housing comprises a metal.

In some embodiments, the housing further includes a top side and a bottom side, wherein the top side, the first sidewall, and the second sidewall may include a plastic, and the bottom side may include a metal.

According to a further aspect of this disclosure, a cooling system includes a first liquid-coolant-block (LCB) disposed on a first optical-module-cage, the first LCB defining a first enclosed volume, and having a plurality of first-inlet/outlet (I/O) ports, each first-I/O port of the plurality of first-I/O ports providing access to the first enclosed volume, a second LCB disposed on a second optical-module-cage, the second LCB defining a second enclosed volume, and having a plurality of second-I/O ports, each second-I/O port of the plurality of second-I/O ports providing access to the second enclosed volume, a first LCB-connector coupled between a first first-I/O port and a first second-I/O port; and a first plug disposed in a second first-I/O port, wherein the first LCB includes a housing having a first sidewall and a second sidewall, a first one of the plurality of first-I/O ports includes a first outer-opening having a first outer-opening-diameter at an outer surface of the first sidewall, a first inner-opening disposed inwardly from the first outer-opening, the first inner-opening having a first inner-opening-diameter that is less than the first outer-opening-diameter, and a second one of the plurality of first-I/O ports includes a second outer-opening having a second outer-diameter at an outer surface of the second sidewall, a second inner-opening disposed inwardly from the second outer-opening, the second inner-opening having a second inner-opening-diameter that is less than the first outer-opening-diameter.

In some embodiments, the first sidewall is chamfered between the first outer-opening and the first inner-opening, and the second sidewall is chamfered between the second outer-opening and the second inner-opening.

In some embodiments, the cooling system further includes a first resilient biasing element disposed above the first LCB and a second resilient biasing element disposed above the second LCB.

In some embodiments, the first optical-module-cage is disposed on a printed circuit board, and configured to receive a pluggable optical module, and the first LCB connector includes a tube having an outer surface, a first end, and a second end opposite the first end, a first circumferential tube-ridge extending outwardly from the outer surface of the tube and disposed a first distance from the first end, a second circumferential tube-ridge extending outwardly from the outer surface of the tube and disposed a second distance from the first end, a third circumferential tube-ridge extending outwardly from the outer surface of the tube and disposed the first distance from the second end, and a fourth circumferential tube-ridge extending outwardly from the outer surface of the tube and disposed the second distance from the second end.

In some embodiments, the first optical-module-cage is disposed on a printed circuit board and configured to receive a first pluggable optical module, the second optical module cage is disposed on the printed circuit board and configured to receive a second pluggable optical module, and the first resilient biasing element comprises a leaf spring. Although printed circuit boards are a very common form of substrate upon which optical-module-cages are disposed, various embodiments are not limited to printed circuit boards, and any suitable substrate material or substrate configuration may be used.

As used herein, the term “vertical/vertically” means nominally orthogonal to the surface of the object being referenced.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances.

As used herein, the term “about” indicates the value of a given quantity may vary from its nominal value based on, for example, various manufacturing tolerances. By way of example, and not limitation, the term “about” may indicate the cited value of a given quantity may vary within, for example, 1–30% of the value (e.g., ±0.5%, ±1%, ±5%, ±10%, ±20%, or ±30% of the value). Specific ranges are provided herein when needed.

Unless stated otherwise, terms such as “first” and “second” are used to arbitrarily distinguish between the elements such terms describe. Thus, these terms are not necessarily intended to indicate temporal or other prioritization of such elements.

It should be appreciated by those skilled in the art that any block diagrams herein represent conceptual views of illustrative hardware embodying the principles of the aspects.

While each of the embodiments are described above in terms of their structural arrangements, it should be appreciated that the aspects also cover the associated methods of using the embodiments described above.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used herein should be construed as critical or essential unless explicitly described as such. Also, as used herein, the articles “a” and “an” are intended to include one or more items, and may be used interchangeably with “one or more.” Furthermore, as used herein, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used herein, the terms “has,” “have,” “having,” and/or the like are intended to be open-ended terms. Further, the phrase “based on” is intended to mean “based, at least in part, on” unless explicitly stated otherwise.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the subjacent claims.

What is claimed is:

1. A liquid-coolant-block-subassembly configured to engage with a liquid-coolant-block for liquid communication, comprising:
a housing defining a main-enclosed-volume, the housing having a housing-wall;
a first inlet/outlet (I/O) port defining a first liquid-communication-path through the housing-wall at a first location thereof, the first liquid-communication-path coupled to the main-enclosed-volume;
a second I/O port defining a second liquid-communication-path through the housing-wall at a second location thereof, the second liquid-communication-path coupled to the main-enclosed-volume; and
a first liquid-coolant-block-connector having a first end, a second end, and a first outer surface,
wherein the first end is engaged with the first I/O port such that the first liquid-coolant-block-connector maintains a liquid-tight seal between the first I/O port and the first outer surface of the first liquid-coolant-block-connector through a range of angular displacement of the housing relative to the second end of the liquid-coolant-block-connector.

2. The liquid-coolant-block-subassembly of claim 1, wherein the first I/O port includes a first outer-opening having a first outer-opening-diameter at the first location of the housing-wall and a first inner-opening disposed inwardly from the first outer-opening, the first inner-opening having a first inner-opening-diameter that is less than the first outer-opening-diameter, and the housing-wall is chamfered between the first outer-opening and the first inner-opening.

3. The liquid-coolant-block-subassembly of claim 1, further comprising:
a second liquid-coolant-block-connector having a third end, a fourth end, and a second outer surface,
wherein the third end is engaged with the second I/O port such that the second liquid-coolant-block-connector maintains a liquid-tight seal between the second I/O port and the second outer surface of the second liquid-coolant-block-connector through a range of angular displacement of the housing relative to the fourth end of the second liquid-coolant-block-connector,
wherein the second I/O port includes a second outer-opening having a second outer-opening-diameter at the second location of the housing-wall and a second inner-opening disposed inwardly from the second outer-opening, the second inner-opening having a second inner-opening-diameter that is less than the second outer-opening-diameter, and the housing-wall is chamfered between the second outer-opening and the second inner-opening.

4. The liquid-coolant-block-subassembly of claim 3, further comprising:
a third I/O port defining a third liquid-communication-path through the housing-wall at a third location thereof, the third liquid-communication-path coupled to the main-enclosed-volume; and
a fourth I/O port defining a fourth liquid-communication-path through the housing-wall at a fourth location thereof, the fourth liquid-communication-path coupled to the main-enclosed-volume,
wherein the first liquid-coolant-block-connector comprises a tube having a first outer surface, a first end, and a second end opposite the first end, a first circumferential tube-ridge extending outwardly from the first outer surface and disposed a first distance from the first end, and a first O-ring disposed on the first outer surface and positioned adjacent to the first circumferential tube-ridge.

5. The liquid-coolant-block-subassembly of claim 1, wherein the housing comprises a metal, a plastic, and a heat slug.

6. A liquid-coolant-block configured to engage with a liquid-coolant-block-subassembly for liquid communication, comprising:
a housing defining a main-enclosed-volume, the housing having a housing-wall;
an inlet/outlet (I/O) port defining a liquid-communication-path through the housing-wall at a first location thereof, the liquid-communication-path coupled to the main-enclosed-volume;
wherein the I/O port includes an outer-opening having an outer-opening-diameter at an outer surface of the housing-wall, and an inner-opening disposed inwardly from the outer-opening, the inner-opening having a inner-opening-diameter that is less than the outer-opening-diameter, and the housing-wall is chamfered at nominally 20 degrees between the outer-opening and the inner-opening.

7. The liquid-coolant-block of claim 6, wherein the I/O port is configured to engage with a first liquid-coolant-block-connector of the liquid-coolant-block-subassembly such that a liquid-tight seal between the I/O port and a first outer surface of the first liquid-coolant-block-connector through a range of angular displacement of the housing relative to the liquid-coolant-block-subassembly is maintained.

8. The liquid-coolant-block of claim 7, wherein the housing-wall comprises a metal.

9. The liquid-coolant-block of claim 7, wherein the housing-wall comprises a plastic.

10. The liquid-coolant-block of claim 7, wherein the liquid-coolant-block further comprises:
a heat slug.

11. A cooling apparatus, comprising:
a first liquid-coolant-block (LCB), the first LCB defining a first enclosed volume, and having a plurality of first-inlet/outlet (I/O) ports, each first-I/O port of the plurality of first-I/O ports providing access to the first enclosed volume;
a second LCB, disposed adjacent to the first LCB, defining a second enclosed volume, and having a plurality of second-I/O ports, each second-I/O port of the plurality of second-I/O ports providing access to the second enclosed volume; and
a first LCB-connector coupled between a first first-I/O port of the first LCB and a first second-I/O port of the second LCB,
wherein the first LCB-connector comprises:
a tube having an outer surface, a first end, and a second end opposite the first end;
a first circumferential tube-ridge extending outwardly from the outer surface of the tube and disposed a first distance from the first end;
a second circumferential tube-ridge extending outwardly from the outer surface of the tube and disposed a second distance from the first end;
a third circumferential tube-ridge extending outwardly from the outer surface of the tube and disposed the first distance from the second end; and
a fourth circumferential tube-ridge extending outwardly from the outer surface of the tube and disposed the second distance from the second end.

12. The cooling apparatus of claim 6, wherein the first LCB-connector further comprises:
a first O-ring disposed on the outer surface of the tube and positioned adjacent to the first circumferential tube-ridge;
a second O-ring disposed on the outer surface of the tube and positioned between the first circumferential tube-ridge and the second circumferential tube-ridge;
a third O-ring disposed on the outer surface of the tube and positioned adjacent to the third circumferential tube-ridge; and
a fourth O-ring disposed on the outer surface of the tube and positioned between the third circumferential tube-ridge and the fourth circumferential tube-ridge.

13. The cooling apparatus of claim 7, further comprising:
a first plug disposed in a second first-I/O port,
wherein the first plug comprises:
a solid cylinder having an outer surface, a first end, and a second end opposite its first end;
a first circumferential plug-ridge extending outwardly from the outer surface of the solid cylinder and disposed a third distance from its first end;
a second circumferential plug-ridge extending outwardly from the outer surface of the solid cylinder and disposed a fourth distance from the first end;
a fifth O-ring disposed on the outer surface of the solid cylinder and positioned adjacent to the first circumferential plug-ridge; and
a sixth O-ring disposed on the outer surface of the solid cylinder and positioned between the first circumferential plug-ridge and the second circumferential plug-ridge.

14. The cooling apparatus of claim 8, wherein the first LCB comprises:
a housing including a heat slug.

15. The cooling apparatus of claim 8, wherein the first LCB comprises:
a housing having a plastic upper portion and a metal bottom portion.

16. A method of removing heat from a plurality of optical modules, comprising:
providing a substrate having a first optical-module-cage disposed thereon, and a second optical-module-cage disposed thereon;
coupling a first liquid-coolant-block (LCB) and a second LCB to each other with a first LCB-connector;
disposing the first LCB on the first optical-module-cage such that it is a first distance from the substrate, and disposing the second LCB on the second optical-module-cage such that it is the first distance from the substrate;
applying a first spring force to maintain the first LCB in contact with the first optical-module-cage;
applying a second spring force to maintain the second LCB in contact with the second optical-module-cage;
inserting a first pluggable optical module in the first optical-module-cage;
inserting a second pluggable optical module in the second optical-module-cage;
supplying power to the first pluggable optical module and to the second optical module; and
flowing a liquid coolant through the first LCB and the second LCB.

17. The method of claim 16, further comprising:
coupling the first LCB and the second LCB to each other with a second LCB-connector.

18. The method of claim 16, wherein the first LCB has a first inlet/outlet (I/O) port in a first sidewall, the first I/O port includes a first outer-opening having a first outer-opening-diameter, a first inner-opening disposed inwardly from the first outer-opening, the first inner-opening having a first inner-opening-diameter that is less than the first outer-opening-diameter, and the first sidewall is chamfered between the first outer-opening and the first inner-opening.

19. The method of claim 18, wherein applying the first spring force comprises disposing a resilient biasing element in contact with the first LCB.

20. The method of claim 19, further comprising connecting the first LCB to a coolant distribution unit.
